(19) United States
(12) Patent Application Publication
(10) Pub. No.: US 2026/0211031 A1
(43) Pub. Date: Jul. 23, 2026

(54) INSPECTION APPARATUS FOR SEMICONDUCTOR WAFER, METHOD FOR INSPECTING SEMICONDUCTOR WAFER, AND NON-TRANSITORY COMPUTER READABLE RECORDING MEDIUM ON WHICH AN INSPECTING PROGRAM IS RECORDED

(71) Applicant: KAI Giken Co., Ltd., Yokohama-shi (JP)

(72) Inventor: Kazuhiro SAKAGUCHI, Yokohama-shi (JP)

(73) Assignee: KAI Giken Co., Ltd., Yokohama-shi (JP)

(21) Appl. No.: 19/419,271

(22) Filed: Dec. 15, 2025

(30) Foreign Application Priority Data
Jan. 21, 2025 (JP) 2025-008237
Apr. 22, 2025 (JP) 2025-070283

(51) Int. Cl. G01R 31/28

(52) U.S. Cl. CPC G01R 31/2891; G01R 31/2887

(57) ABSTRACT

An inspection apparatus for a semiconductor wafer includes: a contact position determination unit that determines semiconductor chips to be contacted by N measurement sites among a plurality of semiconductor chips. The contact position determination unit determines to shift semiconductor chips to be contacted next by N chips in a first direction in a case where there is no semiconductor chip determined as a defective product among N inspected semiconductor chips, and, in a case where there are one or more semiconductor chips determined as defective products among the N inspected semiconductor chips, determines the semiconductor chips to be contacted next so as to make contact between a semiconductor chip located closest to a side in a second direction among the one or more semiconductor chips determined as the defective products and a measurement site located closest to a side in a second direction among the N measurement sites.

### CROSS-REFERENCE TO RELATED APPLICATIONS

The present application claims priority under 35 U.S.C..sctn.119 to Japanese Patent Application No. P2025-008237, filed January 21, 2025 and No. P2025-070283, filed April 22, 2025. The contents of these applications are herein incorporated by reference in their entirety.

### BACKGROUND OF THE INVENTION

### 1. FIELD OF INVENTION

The present invention relates to an inspection apparatus for a semiconductor wafer, a method for inspecting a semiconductor wafer, and non-transitory computer readable recording medium on which an inspecting program is recorded.

### 2. DESCRIPTION OF RELATED ART

JP H6-168991 A discloses an inspection apparatus for a semiconductor wafer that performs inspection (also referred to as a test) on a semiconductor chip formed on a wafer by multi-probing. In such an inspection apparatus for a semiconductor wafer, the inspection time for the semiconductor chip is preferably short in terms of manufacturing cost. The inspection time is proportional to the number of times of contact between a probe and an electrode of the semiconductor chip. Reducing the total number of times of contact is effective for reducing the manufacturing cost. Japanese Patent No. 7498677 discloses an inspection apparatus for a semiconductor wafer capable of reducing the total number of times of contact between a probe and an electrode of a semiconductor chip.

However, the inspection apparatuses for semiconductor wafers described in JP H6-168991 A and Japanese Patent No. 7498677 still have room for improvement in terms of reducing the total number of times of contact.

### SUMMARY OF THE INVENTION

In order to solve at least one of the above-described problems, an inspection apparatus for a semiconductor wafer reflecting one aspect of the present invention includes: N (N is an integer of two or more) measurement sites arranged in at least a specific direction; a tester that makes the N measurement sites contact a plurality of semiconductor chips, formed on a semiconductor wafer and arrayed in the specific direction, and inspects N semiconductor chips in a contact state among the plurality of semiconductor chips; and a determination unit that determines semiconductor chips to be contacted by the N measurement sites among the plurality of semiconductor chips, wherein the determination unit, in a case where there is no semiconductor chip determined as a defective product among the N inspected semiconductor chips, determines to shift semiconductor chips to be contacted next by N chips in a first direction which is one direction of the specific direction, and, in a case where there are semiconductor chips determined as defective products among the N inspected semiconductor chips, determines the semiconductor chips to be contacted next in such a manner as to make contact between a semiconductor chip located closest to a side in a second direction among the semiconductor chips determined as the defective products and a measurement site located closest to the side in the second direction among the N measurement sites, the second direction being another direction of the specific direction.

In addition, in order to solve at least one of the above-described problems, a method for inspecting a semiconductor wafer by an inspection apparatus, which includes N (N is an integer of two or more) measurement sites arranged in at least a specific direction and a tester that makes the N measurement sites contact a plurality of semiconductor chips, formed on a semiconductor wafer and arrayed in the specific direction, and inspects N semiconductor chips in a contact state among the plurality of semiconductor chips, the method reflecting one aspect of the present invention includes a determination step of determining semiconductor chips to be contacted by the N measurement sites among the plurality of semiconductor chips. In the determination step, in a case where there is no semiconductor chip determined as a defective product among the N inspected semiconductor chips, semiconductor chips to be contacted next are determined to be shifted by N chips in a first direction which is one direction of the specific direction, and, in a case where there are semiconductor chips determined as defective products among the N inspected semiconductor chips, the semiconductor chips to be contacted next are determined in such a manner as to make contact between a semiconductor chip located closest to a side in a second direction among the semiconductor chips determined as the defective products and a measurement site located closest to a side in a second direction among the N measurement sites, the second direction being another direction of the specific direction.

In addition, in order to solve at least one of the above-described problems, a computer-readable recording medium reflecting one aspect of the present invention stores an inspection program for causing a computer to function as the inspection apparatus for a semiconductor wafer described above.

### BRIEF DESCRIPTION OF THE DRAWINGS

FIG. 1 is a configuration diagram illustrating an example of an inspection apparatus for a semiconductor wafer according to a first embodiment;

FIG. 2 is a configuration diagram illustrating a control configuration of the inspection apparatus for a semiconductor wafer according to the first embodiment;

FIG. 3 is a schematic view illustrating a semiconductor chip formed on a semiconductor wafer;

FIG. 4 is a schematic view illustrating a probe card;

FIG. 5 is a conceptual view illustrating an order of inspection of the semiconductor chips;

FIG. 6A is a schematic view illustrating a state of inspection including re-inspection according to a comparative example, and illustrates a state of initial inspection in a specific row;

FIG. 6B is a schematic view illustrating a state of the inspection including the re-inspection according to the comparative example, and illustrates a state of the re-inspection in the specific row;

FIG. 7 is a schematic view illustrating a state of inspection including re-inspection by an efficient probing method, and illustrates a state of inspection in a specific row;

FIG. 8A is a first schematic view illustrating a state of the inspection including the re-inspection according to the first embodiment, and illustrates a first step in a specific row;

FIG. 8B is the first schematic view illustrating a state of the inspection including the re-inspection according to the first embodiment, and illustrates a second step in the specific row;

FIG. 8C is the first schematic view illustrating a state of the inspection including the re-inspection according to the first embodiment, and illustrates a third step in the specific row;

FIG. 8D is the first schematic view illustrating a state of the inspection including the re-inspection according to the first embodiment, and illustrates a fourth step in the specific row;

FIG. 8E is the first schematic view illustrating a state of the inspection including the re-inspection according to the first embodiment, and illustrates a fifth step in the specific row;

FIG. 8F is the first schematic view illustrating a state of the inspection including the re-inspection according to the first embodiment, and illustrates a sixth step in the specific row;

FIG. 9A is the first schematic view illustrating a state of the inspection including the re-inspection according to the first embodiment, and illustrates a seventh step in the specific row;

FIG. 9B is the first schematic view illustrating a state of the inspection including the re-inspection according to the first embodiment, and illustrates an eighth step in the specific row;

FIG. 9C is the first schematic view illustrating a state of the inspection including the re-inspection according to the first embodiment, and illustrates a ninth step in the specific row;

FIG. 9D is the first schematic view illustrating a state of the inspection including the re-inspection according to the first embodiment, and illustrates a tenth step in the specific row;

FIG. 9E is the first schematic view illustrating a state of the inspection including the re-inspection according to the first embodiment, and illustrates an eleventh step in the specific row;

FIG. 10 is a table illustrating the total number of times of contact in a case where the percentage of the number of semiconductor chips determined as non-defective products in the initial inspection is 95%;

FIG. 11 is a table illustrating the total number of times of contact in a case where the percentage of the number of semiconductor chips determined as non-defective products in the initial inspection is 75%;

FIG. 12 is a table illustrating the total number of times of contact in a case where the percentage of the number of semiconductor chips determined as non-defective products in the initial inspection is 50%;

FIG. 13A is a second schematic view illustrating a state of the inspection including the re-inspection according to the first embodiment, and illustrates a specific step in the specific row;

FIG. 13B is the second schematic view illustrating a state of the inspection including the re-inspection according to the first embodiment, and illustrates a state before adjustment in a step next to the specific step in the specific row;

FIG. 13C is the second schematic view illustrating a state of the inspection including the re-inspection according to the first embodiment, and illustrates a state after the adjustment in the step next to the specific step in the specific row;

FIG. 14A is a third schematic view illustrating a state of the inspection including the re-inspection according to the first embodiment, and illustrates a specific step in the specific row;

FIG. 14B is the third schematic view illustrating a state of the inspection including the re-inspection according to the first embodiment, and illustrates a state before adjustment in a step next to the specific step in the specific row;

FIG. 14C is the third schematic view illustrating a state of the inspection including the re-inspection according to the first embodiment, and illustrates a state after the adjustment in the step next to the specific step in the specific row;

FIG. 15 is a flowchart illustrating a method for inspecting a semiconductor wafer according to the first embodiment;

FIG. 16A is a first schematic view illustrating a state of inspection including re-inspection according to a second embodiment, and illustrates a state before first adjustment in a specific row;

FIG. 16B is the first schematic view illustrating a state of inspection including re-inspection according to a second embodiment, and illustrates a state after first adjustment in a specific row;

FIG. 16C is the first schematic view illustrating a state of the inspection including the re-inspection according to the second embodiment, and illustrates a state before second adjustment in the specific row;

FIG. 16D is the first schematic view illustrating a state of the inspection including the re-inspection according to the second embodiment, and illustrates a state after the second adjustment in the specific row;

FIG. 17A is a second schematic view illustrating a state of the inspection including the re-inspection according to the second embodiment, and illustrates a state before the first adjustment in a specific row;

FIG. 17B is the second schematic view illustrating a state of the inspection including the re-inspection according to the second embodiment, and illustrates a state after the first adjustment in a specific row;

FIG. 17C is the second schematic view illustrating a state of the inspection including the re-inspection according to the second embodiment, and illustrates a state before the second adjustment in the specific row;

FIG. 17D is the second schematic view illustrating a state of the inspection including the re-inspection according to the second embodiment, and illustrates a state after the second adjustment in the specific row;

FIG. 18 is a flowchart illustrating a method for inspecting a semiconductor wafer according to the second embodiment;

FIG. 19 is a flowchart illustrating a method for inspecting a semiconductor wafer according to a third embodiment;

FIG. 20 is a flowchart illustrating a method for inspecting a semiconductor wafer according to a fourth embodiment;

FIG. 21 is a schematic view illustrating a probe card of an inspection apparatus for a semiconductor wafer according to a fifth embodiment;

FIG. 22A is a schematic view illustrating another example of the probe card according to the fifth embodiment, and illustrates a first example;

FIG. 22B is a schematic view illustrating still another example of the probe card according to the fifth embodiment, and illustrates a second example;

FIG. 22C is a schematic view illustrating still another example of the probe card according to the fifth embodiment, and illustrates a third example;

FIG. 22D is a schematic view illustrating still another example of the probe card according to the fifth embodiment, and illustrates a fourth example;

FIG. 23A is a schematic view illustrating a state of inspection including re-inspection according to the fifth embodiment, and illustrates a first step;

FIG. 23B is a schematic view illustrating a state of the inspection including the re-inspection according to the fifth embodiment, and illustrates a second step;

FIG. 23C is a schematic view illustrating a state of the inspection including the re-inspection according to the fifth embodiment, and illustrates a third step;

FIG. 23D is a schematic view illustrating a state of the inspection including the re-inspection according to the fifth embodiment, and illustrates a fourth step;

FIG. 23E is a schematic view illustrating a state of the inspection including the re-inspection according to the fifth embodiment, and illustrates a fifth step;

FIG. 23F is a schematic view illustrating a state of the inspection including the re-inspection according to the fifth embodiment, and illustrates a sixth step;

FIG. 24 is a plan view illustrating a semiconductor wafer used in simulation according to the fifth embodiment;

FIG. 25 is a table illustrating simulation results according to the fifth embodiment;

FIG. 26 is a graph illustrating the simulation results according to the fifth embodiment; and

FIG. 27 is a flowchart illustrating a method for inspecting a semiconductor wafer according to the fifth embodiment.

### DETAILED DESCRIPTION OF THE PREFERRED EMBODIMENT

Hereinafter, a description is given of embodiments of the present invention with reference to the drawings.

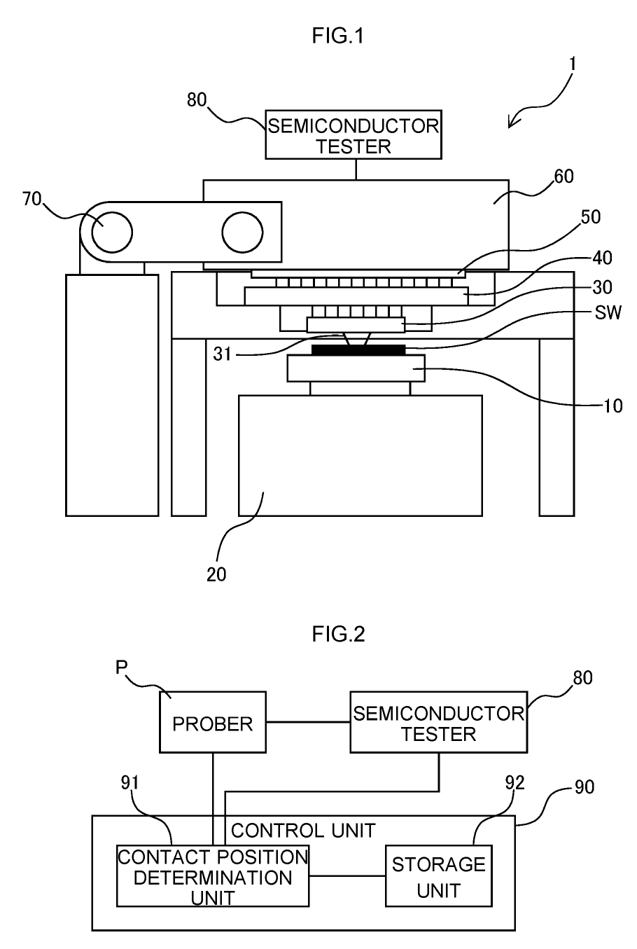

FIG. 1 is a configuration diagram illustrating an example of an inspection apparatus for a semiconductor wafer according to a first embodiment. FIG. 2 is a configuration diagram illustrating a control configuration of the inspection apparatus for a semiconductor wafer according to the first embodiment.

An inspection apparatus 1 for semiconductor wafers SW inspects each of semiconductor chips of the semiconductor wafer SW. As illustrated in FIG. 1, the inspection apparatus 1 includes a wafer chuck 10, a moving mechanism 20, a probe card 30, a frog ring 40, a performance board 50, a test head 60, and a rotating shaft 70. As also illustrated in FIG. 2, the inspection apparatus 1 includes a semiconductor tester (tester) 80.

The wafer chuck 10 holds the semiconductor wafer SW. The moving mechanism 20 moves and rotates the wafer chuck 10 in three dimensions. The probe card 30 includes a probe 31 that comes into contact with an electrode pad formed on the semiconductor chip. The probe card 30 has a connection terminal electrically connected to the probe 31 on the upper side. The frog ring 40 is a connection member for connecting the connection terminal located on the upper side of the probe card 30 to the test head 60. The test head 60 is connected to the semiconductor tester 80. The test head 60 applies an electric signal from the semiconductor tester 80 to the semiconductor chip. The test head 60 receives an output signal corresponding to the applied signal from the semiconductor chip and returns the received signal to the semiconductor tester 80. The performance board 50 is attached to the test head 60 for connection with the frog ring 40. The test head 60 and the performance board 50 rotate about the rotating shaft 70. The test head 60 and the performance board 50 can be separated from others. Parts of the inspection apparatus 1 other than the test head 60 are generally called a prober P.

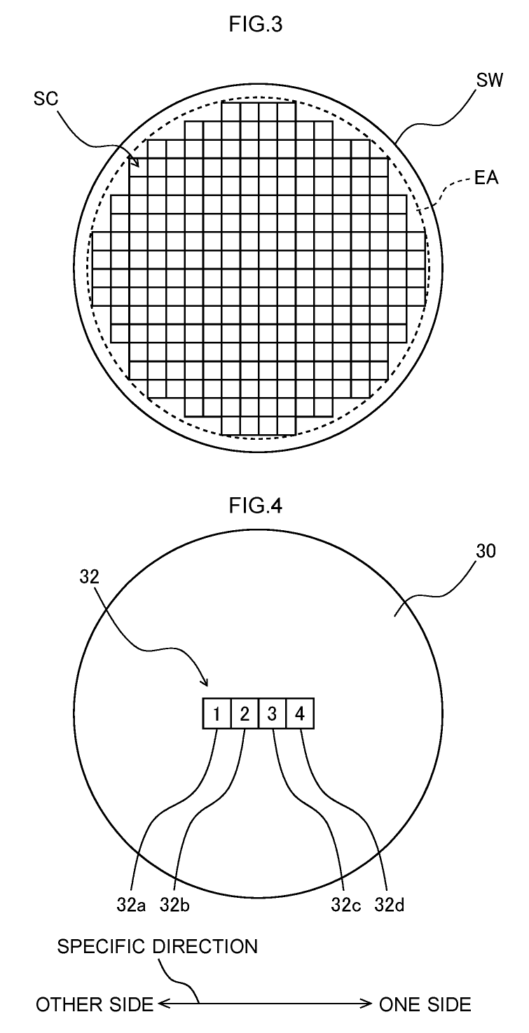

FIG. 3 is a schematic view illustrating the semiconductor chips formed on the semiconductor wafer SW. As illustrated in FIG. 3, a large number of semiconductor chips SC are arranged in a grid pattern on the semiconductor wafer SW. Note that the semiconductor wafer SW also has an area where the semiconductor chip SC cannot be formed, the area being present outside an effective area EA. In FIG. 3, a dashed circle indicates the effective area EA.

FIG. 4 is a schematic view illustrating the probe card 30. The probe card 30 has N (N is an integer of two or more) measurement sites 32. Each of the measurement sites 32 has the probe 31 in contact with an electrode pad formed on the semiconductor chip SC. Each of the probes 31 of the measurement sites 32 comes into contact with (hereinafter, also referred to as contacts) the electrode pad of the corresponding semiconductor chip SC. In FIG. 4, four measurement sites 32 are provided in a row in a specific direction. Among these measurement sites 32, a first measurement site 32a is provided on the other side in the specific direction. The measurement sites 32 include a second measurement site 32b, a third measurement site 32c, and a fourth measurement site 32d provided in order from the first measurement site 32a toward one side in the specific direction. The following description is given assuming that N = 4.

As illustrated in FIG. 2, the inspection apparatus 1 further includes a controller 90. The controller 90 controls the prober P and the semiconductor tester 80, and includes a contact position determination unit (determination unit) 91 and a storage unit (non-transitory computer readable recording medium) 92. The storage unit 92 stores an operation program for operating the inspection apparatus 1, various setting values, and the like. The storage unit 92 also provides a temporary storage area during the operation. The contact position determination unit 91 determines which semiconductor chips SC among the plurality of semiconductor chips SC on the semiconductor wafer SW are to be contacted with the probes 31 of the plurality of measurement sites 32. The prober P operates the moving mechanism 20 according to this determination to make the probes 31 of the plurality of measurement sites 32 contact the semiconductor chips SC.

Next, a method for inspecting the semiconductor wafer SW by the inspection apparatus 1 according to the first embodiment will be described. First, the semiconductor wafer SW is held by the wafer chuck 10. Thereafter, the controller 90 controls the moving mechanism 20 such that the probe 31 of each of the measurement sites 32 contacts the electrode pad on each of the semiconductor chips SC equally and accurately.

Next, the controller 90 brings the probe card 30 close to the semiconductor wafer SW. Then, the controller 90 brings the probes 31 of the measurement sites 32 into contact and to be electrically coupled with the electrode pads of the semiconductor chips SC. Next, the semiconductor tester 80 applies an electric signal to each of the semiconductor chips SC via the test head 60 under the control of the controller 90. Then, the semiconductor tester 80 receives an output signal from each of the semiconductor chips SC corresponding to the electric signal, and determines whether the output signal indicates a predetermined value. As a result, it is determined whether each of the semiconductor chips SC is a non-defective product or a defective product.

Thereafter, the controller 90 performs inspection on the next semiconductor chips SC. That is, the controller 90 moves the probe card 30 away from the semiconductor wafer SW and brings the probes 31 of the measurement sites 32 into contact with the electrode pads of the uninspected semiconductor chips SC. Next, application of an electric signal, reception of an output signal, and determination are performed to determine whether each of the semiconductor chips SC is a non-defective product or a defective product. Thereafter, all the semiconductor chips SC on the semiconductor wafer SW are inspected in the same manner.

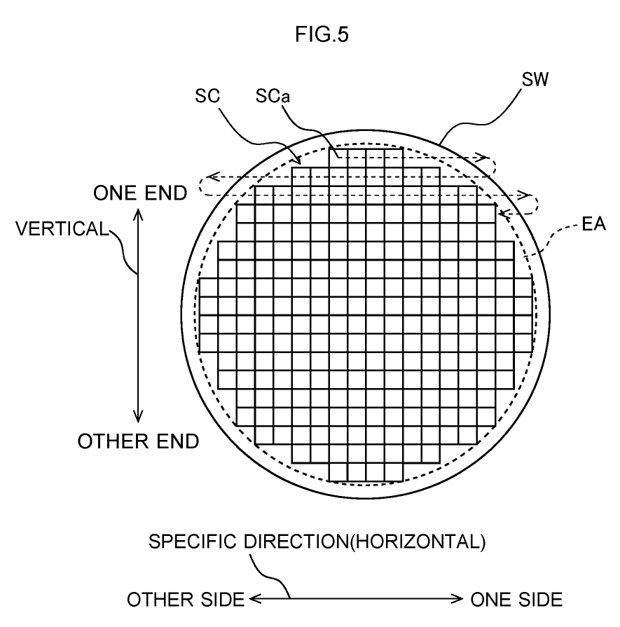

FIG. 5 is a conceptual view illustrating an order of inspection of the semiconductor chips SC. As illustrated in FIG. 5, the controller 90 starts measurement from semiconductor chips SCa at an end of the semiconductor wafer SW. More specifically, the controller 90 performs inspection from the semiconductor chips SC in a row (horizontal row) on the most one end side illustrated in FIG. 5 to a row on the other end side while moving the semiconductor wafer SW in a zigzag manner from the other side to the one side or from the one side to the other side. At this time, the controller 90 performs the inspection by causing the probes 31 to sequentially contact the semiconductor chips SC, and performs the inspection up to the semiconductor chips SC in a row on the most other end side. In the following description, a direction in which the plurality of measurement sites 32 advance in each row is referred to as a first direction, and a direction opposite to the first direction is referred to as a second direction. The first direction and the second direction are along the specific direction.

In addition, the controller 90 may perform inspection in a zigzag manner from the one end side to the other end side or from the other end side to the one end side from the semiconductor chips SC in the row (vertical row) on the most other side toward a row on the one side.

Here, when each of the semiconductor chips SC formed on the semiconductor wafer SW is determined as a defective product in the first inspection (hereinafter referred to as the initial inspection), the second inspection (hereinafter referred to as the re-inspection) may be performed. This is because even the semiconductor chip SC, which is a non-defective product, is sometimes determined as a defective product in the initial inspection for some reason. For example, when a contact state between the probe 31 of the probe card 30 and the electrode pad of the semiconductor chip SC is not appropriate, even the semiconductor chip SC, which is a non-defective product, is determined as a defective product. Therefore, the inspection apparatus 1 performs the re-inspection on the semiconductor chips SC determined as defective products, thereby increasing the number of the semiconductor chips SC determined as non-defective products as compared with a case where only the initial inspection is performed. The re-inspection may be repeated not only once but also twice or more.

Next, an inspection method according to a comparative example will be described prior to a description regarding a method for inspecting the semiconductor wafer SW by the inspection apparatus 1 according to the first embodiment, the method including the re-inspection.

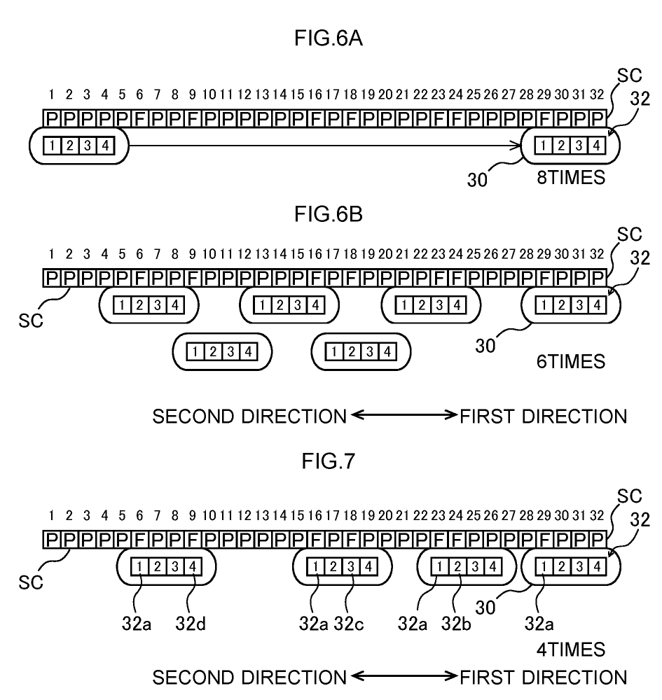

FIGS. 6A and 6B are schematic views illustrating states of inspection including re-inspection according to the comparative example, and illustrate states of inspection in a specific row. In FIGS. 6A and 6B, it is assumed that the number of the semiconductor chips SC in the specific row is 32, and numbers of Coordinates 1 to 32 are assigned to the semiconductor chips SC, respectively. In addition, it is assumed that the plurality of measurement sites 32 can simultaneously contact four adjacent semiconductor chips SC.

First, positions of the semiconductor chips SC to be contacted by the probe card 30 are set in advance. As illustrated in FIG. 6A, an inspection apparatus according to the comparative example first performs the initial inspection on the semiconductor chips SC at Coordinates 1 to 4, and sequentially performs the initial inspection on the semiconductor chips SC at and after Coordinate 5 four by four. As a result, the number of inspections in the initial inspection is eight. Here, it is assumed that, in the initial inspection, the semiconductor chips SC at Coordinates 6, 9, 16, 18, 23, 24, and 29 are determined as defective products (“F” in FIGS. 6A and 6B), and the remaining semiconductor chips SC are determined as non-defective products (“P” in FIGS. 6A and 6B). At this time, the re-inspection is performed on the semiconductor chips SC at Coordinates 6, 9, 16, 18, 23, 24, and 29. Here, since the contact positions of the probe card 30 with respect to the semiconductor chips SC are set in advance, the re-inspection is performed as illustrated in FIG. 6B. That is, the re-inspection is performed on the semiconductor chips SC at Coordinates 5 to 8, 9 to 12, 13 to 16, 17 to 20, 21 to 24, and 29 to 32. In the example of FIG. 6B, the re-inspection is not performed on the semiconductor chips SC at Coordinates 1 to 4 and 25 to 28. From the above, the number of inspections in the re-inspection is six.

Here, since the inspection time of the semiconductor chip SC is proportional to the number of inspections (the number of times of contact), reducing the total number of times of contact required to inspect one semiconductor wafer SW is effective for reducing manufacturing cost. Therefore, there is proposed an efficient probing method described in Japanese Patent No. 7498677. Note that the method illustrated in FIGS. 6A and 6B is referred to as a conventional method.

FIG. 7 is a schematic view illustrating a state of inspection including re-inspection by an efficient probing method, and illustrates a state of inspection in a specific row; In the efficient probing method, the same as that in the conventional method applies for the initial inspection.

In the efficient probing method illustrated in FIG. 7, the controller first makes contact between the first measurement site 32a and the semiconductor chip SC at Coordinate 6 determined as a defective product when the re-inspection starts. At the same time, contact is also made between the fourth measurement site 32d and the semiconductor chip SC at Coordinate 9 determined as a defective product. Thus, the semiconductor chips SC at Coordinates 6 and 9 are simultaneously re-inspected.

Next, the controller 90 makes contact between the first measurement site 32a and the semiconductor chip SC at Coordinate 16 determined as a defective product. At the same time, contact is also made between the third measurement site 32c and the semiconductor chip SC at Coordinate 18 determined as a defective product. Thus, the semiconductor chips SC at Coordinates 16 and 18 are simultaneously re-inspected.

Similarly, the controller 90 re-inspects Coordinates 23 to 26 and Coordinates 29 to 32, whereby all the semiconductor chips SC determined as defective products in the initial inspection can be re-inspected. As described above, in the efficient probing method, the contact is made eight times in the initial inspection, and the contact is made four times in the re-inspection. Thus, the number of times of contact is twelve in total, and the efficient probing method requires a smaller number of times of contact up to the re-inspection, the number being smaller by two than the number of times of contact, which is fourteen, in the conventional method.

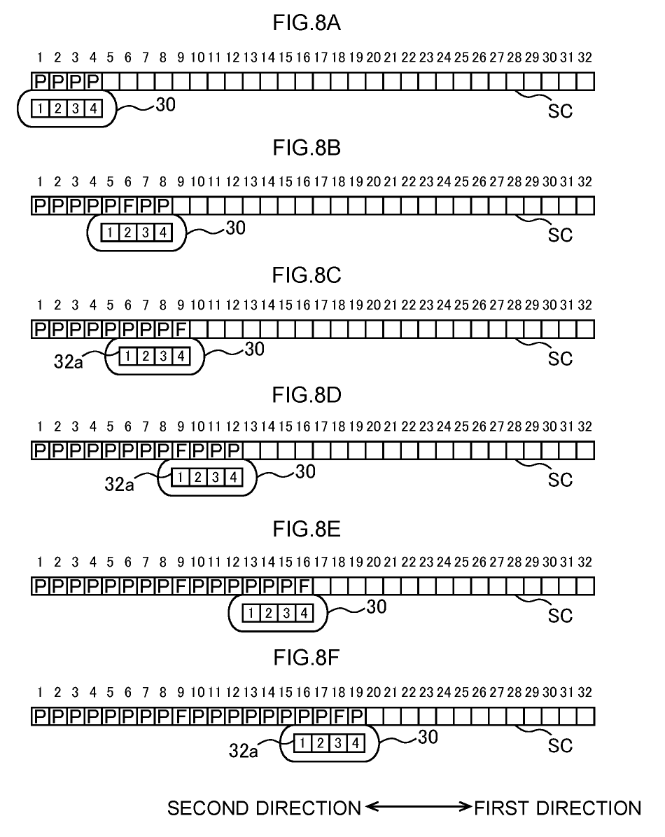

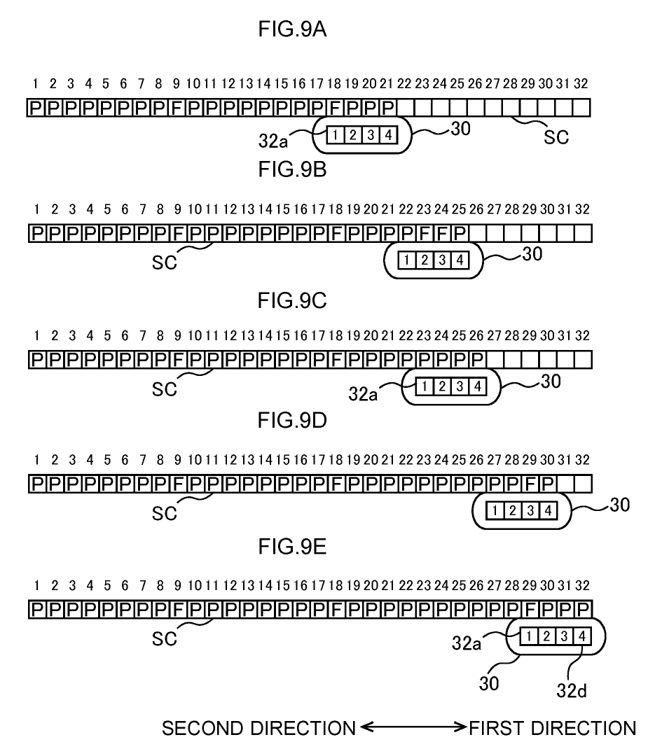

Next, a state of inspection including re-inspection according to the first embodiment will be described. FIGS. 8A to 9E are first schematic views illustrating states of the inspection including the re-inspection according to the first embodiment, and illustrate states of the inspection in a specific row. In the example illustrated in FIGS. 8A to 9E, it is assumed that the number of re-inspections is one. Note that the following inspection method according to the first embodiment is referred to as a sequential method.

First, as illustrated in FIG. 8A, in the first inspection, the contact position determination unit 91 determines to make the probe card 30 contact the semiconductor chips SC at Coordinates 1 to 4. Then, the inspection is performed. It is assumed that all the semiconductor chips SC are determined as non-defective products in the first inspection.

Next, as illustrated in FIG. 8B, in the second inspection, the contact position determination unit 91 determines to make the probe card 30 contact the semiconductor chips SC at Coordinates 5 to 8. That is, in a case where there is no semiconductor chip SC determined as a defective product in the first inspection, the contact position determination unit 91 determines to shift the semiconductor chips SC to be contacted in the second inspection by four in the first direction. Then, the inspection is performed. In the second inspection, it is assumed that only the semiconductor chip SC at Coordinate 6 is determined as a defective product.

Next, as illustrated in FIG. 8C, in the third inspection, the contact position determination unit 91 determines to make the probe card 30 contact the semiconductor chips SC at Coordinates 6 to 9. That is, the contact position determination unit 91 determines to make contact, in the third inspection, between the first measurement site 32a and the semiconductor chip SC at Coordinate 6 determined as the defective product in the second inspection. As a result, the semiconductor chip SC at Coordinate 6 is subjected to the re-inspection, and the semiconductor chips SC at Coordinate 9 is subjected to the initial inspection. Then, it is assumed that the semiconductor chips SC at Coordinate 6 is determined as non-defective products and the semiconductor chip SC at Coordinate 9 is determined as a defective product.

Next, as illustrated in FIG. 8D, in the fourth inspection, the contact position determination unit 91 determines to make the probe card 30 contact the semiconductor chips SC at Coordinates 9 to 12. That is, the contact position determination unit 91 determines to make contact, in the fourth inspection, between the first measurement site 32a and the semiconductor chip SC at Coordinate 9 determined as the defective product in the third inspection. As a result, the semiconductor chip SC at Coordinate 9 is subjected to the re-inspection, and the semiconductor chips SC at Coordinates 10 to 12 are subjected to the initial inspection. Then, it is assumed that the semiconductor chip SC at Coordinate 9 is determined as the defective product, and the semiconductor chips SC at Coordinates 10 to 12 are determined as non-defective products.

Thereafter, as illustrated in FIG. 8E, in the fifth inspection, the contact position determination unit 91 determines to make the probe card 30 contact the semiconductor chips SC at Coordinates 13 to 16. In the example illustrated in FIGS. 8A to 9E, the number of re-inspections is one. Therefore, the re-inspection is not additionally performed on the semiconductor chip SC at Coordinate 9 determined as the defective product. In the fourth inspection, the semiconductor chips SC at Coordinates 10 to 12 are determined as the non-defective products. Therefore, the contact position determination unit 91 determines to make the probe card 30 contact the semiconductor chips SC at Coordinates 13 to 16. Then, the inspection is performed. In the fifth inspection, it is assumed that only the semiconductor chip SC at Coordinate 16 is determined as a defective product.

Next, as illustrated in FIG. 8F, in the sixth inspection, the contact position determination unit 91 determines to make the probe card 30 contact the semiconductor chips SC at Coordinates 16 to 19. That is, the contact position determination unit 91 determines to make contact between the first measurement site 32a and the semiconductor chip SC at Coordinate 16 determined as the defective product in the fifth inspection. As a result, the semiconductor chip SC at Coordinate 16 is subjected to the re-inspection, and the semiconductor chips SC at Coordinates 17 to 19 are subjected to the initial inspection. Then, it is assumed that the semiconductor chip SC at Coordinate 18 is determined as a defective product, and the semiconductor chips SC at Coordinates 16, 17, and 19 are determined as non-defective products.

Next, as illustrated in FIG. 9A, in the seventh inspection, the contact position determination unit 91 determines to make the probe card 30 contact the semiconductor chips SC at Coordinates 18 to 21. That is, the contact position determination unit 91 determines to make contact between the first measurement site 32a and the semiconductor chip SC at Coordinate 18 determined as the defective product in the sixth inspection. As a result, the semiconductor chips SC at Coordinate 18 is subjected to the re-inspection, and the semiconductor chips SC at Coordinates 20 and 21 are subjected to the initial inspection. Then, it is assumed that the semiconductor chip SC at Coordinate 18 is determined as the defective product, and the semiconductor chips SC at Coordinates 20 and 21 are determined as non-defective products.

Thereafter, as illustrated in FIG. 9B, in the eighth inspection, the contact position determination unit 91 determines to make the probe card 30 contact the semiconductor chips SC at Coordinates 22 to 25. Here, the number of re-inspections is one. Thus, the re-inspection is not additionally performed on the semiconductor chip SC at Coordinate 18 determined as the defective product in the seventh inspection. In addition, the semiconductor chips SC at Coordinates 19 to 21 are determined as the non-defective products. Therefore, the contact position determination unit 91 determines to make the probe card 30 contact the semiconductor chips SC at Coordinates 22 to 25. Then, the inspection is performed. In the eighth inspection, it is assumed that the semiconductor chips SC at Coordinates 23 and 24 are determined as defective products.

Next, as illustrated in FIG. 9C, in the ninth inspection, the contact position determination unit 91 determines to make the probe card 30 contact the semiconductor chips SC at Coordinates 23 to 26. That is, the contact position determination unit 91 determines to make contact between the first measurement site 32a and any one on the most second direction side (the semiconductor chip SC at Coordinate 23) out of the semiconductor chips SC at Coordinates 23 and 24 determined as the defective products in the eighth inspection. As a result, the semiconductor chips SC at Coordinates 23 and 24 are subjected to the re-inspection, and the semiconductor chips SC at Coordinate 26 is subjected to the initial inspection. Then, it is assumed that all the semiconductor chips SC are determined as non-defective products.

Next, as illustrated in FIG. 9D, in the tenth inspection, the contact position determination unit 91 determines to make the probe card 30 contact the semiconductor chips SC at Coordinates 27 to 30. That is, since there is no semiconductor chip SC determined as a defective product in the ninth inspection, the contact position determination unit 91 determines to shift the semiconductor chips SC to be contacted next by four in the first direction. Then, the inspection is performed. In the tenth inspection, it is assumed that only the semiconductor chip SC at Coordinate 29 is determined as a defective product.

Thereafter, as illustrated in FIG. 9E, in the eleventh inspection, the contact position determination unit 91 determines to make the probe card 30 contact the semiconductor chips SC at Coordinates 29 to 32. That is, the contact position determination unit 91 determines to make contact between the first measurement site 32a and the semiconductor chip SC at Coordinate 29 determined as the defective product in the tenth inspection. Then, the inspection is performed. In the eleventh inspection, only the semiconductor chip SC at Coordinate 29 is determined as the defective product, and the inspection including the re-inspection ends.

Here, as illustrated in FIGS. 8A to 9E, seven semiconductor chips SC at the same coordinate positions as those in the efficient probing method illustrated in FIG. 7 are determined as the defective products in the initial inspection. However, the number of times of contact in the sequential method according to the first embodiment is eleven including the initial inspection and the one-time re-inspection, which is smaller than twelve in the efficient probing method.

Next, results of simulation related to the number of times of contact will be described. In the simulation, instead of calculating the number of times of contact of the probe card 30 with respect to the semiconductor chips SC formed in a grid pattern on the semiconductor wafer SW, the number of times of contact of the probe card 30 with respect to the semiconductor chips SC present in one row is calculated. This is because results can be more clearly interpreted when the number of times of contact of the probe card 30 is calculated for the semiconductor chips SC in one row than when the number of times of contact of the probe card is calculated for the entire semiconductor wafer SW, the number of times of contact with the entire semiconductor wafer SW is actually the sum of the numbers of times of contact in the respective rows, the number of the semiconductor chips SC on the semiconductor wafer SW differs depending on the row, and the like.

In the simulation, the number of the semiconductor chips SC present in one row was set to 10 to 200 in increments of 10, three types of the percentage of non-defective products in the initial inspection of 95%, 75%, and 50% were set, and the number of the measurement sites 32 present in the probe card 30 was set to 3 to 5. In addition, the measurement sites 32 were adjacent to each other, and the total number of times of contact required for testing the semiconductor chips SC in one row was calculated. The number of trials was set to 1000 times under each condition, and a position of the semiconductor chip SC to be a defective product was randomly determined according to the percentage of non-defective products in the initial inspection.

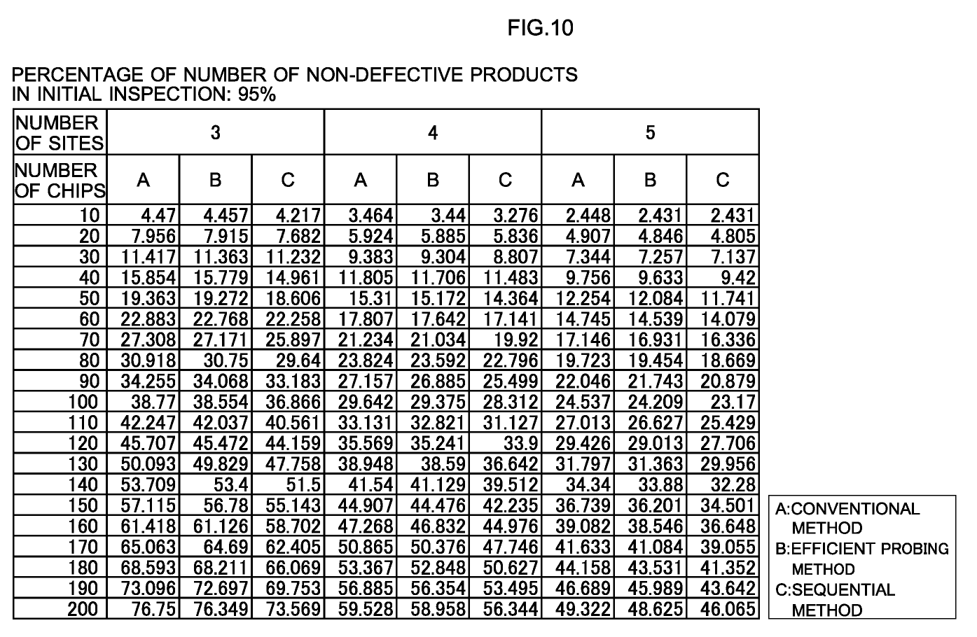

FIG. 10 is a table illustrating the total number of times of contact in a case where the percentage of the number of semiconductor chips determined as non-defective products in the initial inspection is 95%. FIG. 10 illustrates the total number of times of contact (average value) in a case where the simulation was performed 1000 times under each condition.

As illustrated in FIG. 10, for example, in a case where the number of measurement sites was “3” and the number of semiconductor chips was “10”, the average of the total number of times of contact in the conventional method was 4.47, and the average of the total number of times of contact in the efficient probing method was 4.457. In addition, the average of the total number of times of contact in the sequential method was 4.217. That is, a method with the smallest total number of times of contact was the sequential method.

Similarly, for example, in a case where the number of measurement sites was “4” and the number of semiconductor chips was “100”, the average of the total number of times of contact in the conventional method was 29.642, and the average of the total number of times of contact in the efficient probing method was 29.375. In addition, the average of the total number of times of contact in the sequential method was 28.312. Also in this case, the method with the smallest total number of times of contact was the sequential method.

Further, for example, in a case where the number of measurement sites was “5” and the number of semiconductor chips was “200”, the average of the total number of times of contact in the conventional method was 49.322, and the average of the total number of times of contact in the efficient probing method was 48.625. In addition, the average of the total number of times of contact in the sequential method was 46.065. Also in this case, the method with the smallest total number of times of contact was the sequential method.

Further, even in cases other than the above three examples, the method with the smallest total number of times of contact was always the sequential method. Note that, in a case where the number of measurement sites was “5” and the number of semiconductor chips was “10”, it seems like the total number of times of contact was the same in both the efficient probing method and the sequential method in terms of significant figures, but the total number of times of contact in the sequential method was actually smaller.

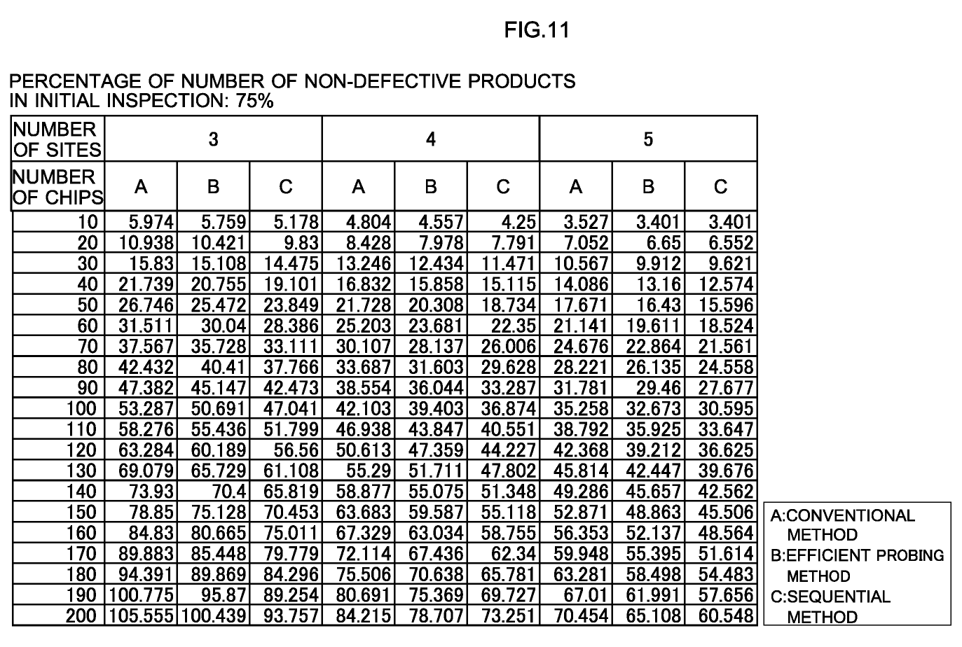

FIG. 11 is a table illustrating the total number of times of contact in a case where the percentage of the number of semiconductor chips determined as non-defective products in the initial inspection is 75%. Also in FIG. 11, the simulation was performed under each of the same conditions as in FIG. 10, and the total number of times of contact (average value) was calculated.

As illustrated in FIG. 11, for example, in a case where the number of measurement sites was “3” and the number of semiconductor chips was “200”, the average of the total number of times of contact in the conventional method was 105.555, and the average of the total number of times of contact in the efficient probing method was 100.439. In addition, the average of the total number of times of contact in the sequential method was 93.757. That is, a method with the smallest total number of times of contact was the sequential method.

Similarly, for example, in a case where the number of measurement sites was “4” and the number of semiconductor chips was “10”, the average of the total number of times of contact in the conventional method was 4.804, and the average of the total number of times of contact in the efficient probing method was 4.557. In addition, the average of the total number of times of contact in the sequential method was 4.25. Also in this case, the method with the smallest total number of times of contact was the sequential method.

Further, for example, in a case where the number of measurement sites was “5” and the number of semiconductor chips was “100”, the average of the total number of times of contact in the conventional method was 35.258, and the average of the total number of times of contact in the efficient probing method was 32.673. In addition, the average of the total number of times of contact in the sequential method was 30.595. Also in this case, the method with the smallest total number of times of contact was the sequential method.

Further, even in cases other than the above three examples, the method with the smallest total number of times of contact was always the sequential method. Note that similar results as those in FIG. 10 were obtained in a case where the number of measurement sites was “5” and the number of semiconductor chips was “10”, and the total number of times of contact in the sequential method was actually the smallest.

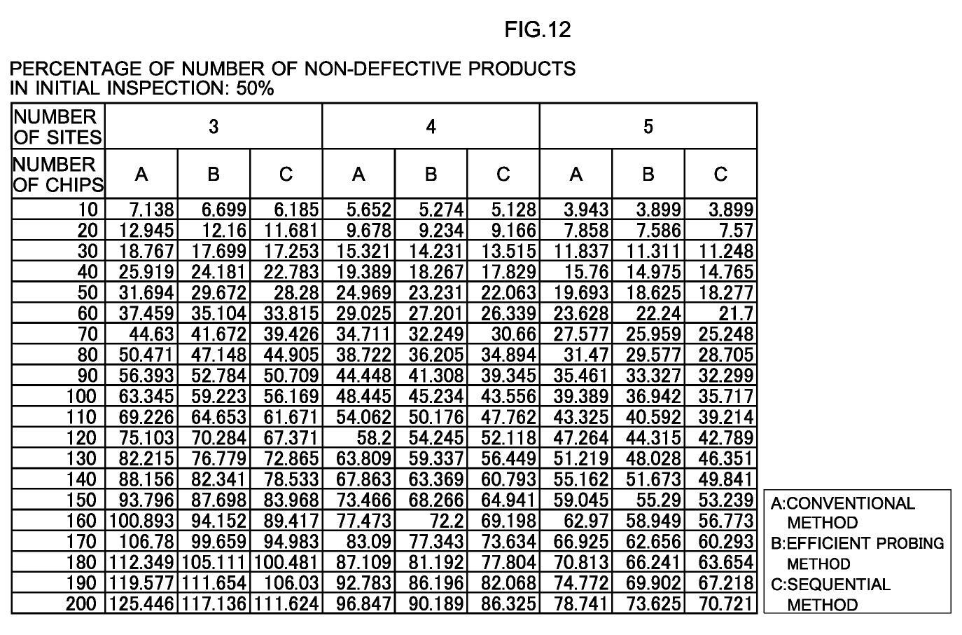

FIG. 12 is a table illustrating the total number of times of contact in a case where the percentage of the number of semiconductor chips determined as non-defective products in the initial inspection is 50%. Also in FIG. 12, the simulation was performed under each of the same conditions as in FIG. 10, and the total number of times of contact (average value) was calculated.

As illustrated in FIG. 12, for example, in a case where the number of measurement sites was “3” and the number of semiconductor chips was “100”, the average of the total number of times of contact in the conventional method was 63.345, and the average of the total number of times of contact in the efficient probing method was 59.223. In addition, the average of the total number of times of contact in the sequential method was 56.169. That is, a method with the smallest total number of times of contact was the sequential method.

Similarly, for example, in a case where the number of measurement sites was “4” and the number of semiconductor chips was “200”, the average of the total number of times of contact in the conventional method was 96.847, and the average of the total number of times of contact in the efficient probing method was 90.189. In addition, the average of the total number of times of contact in the sequential method was 86.325. Also in this case, the method with the smallest total number of times of contact was the sequential method.

Further, for example, in a case where the number of measurement sites was “5” and the number of semiconductor chips was “10”, the average of the total number of times of contact in the conventional method was 3.943, and the average of the total number of times of contact in the efficient probing method was 3.899. In addition, the average of the total number of times of contact in the sequential method was 3.899. Also in this case, the method with the smallest total number of times of contact was the sequential method. Although the total number of times of contact was the same in both the efficient probing method and the sequential method in terms of significant figures, the total number of times of contact in the sequential method was actually smaller.

In addition, even in cases other than the above three examples, the method with the smallest total number of times of contact was always the sequential method.

As described above, also from the simulation results, it has been found that the total number of times of contact can be reduced by performing the sequential method.

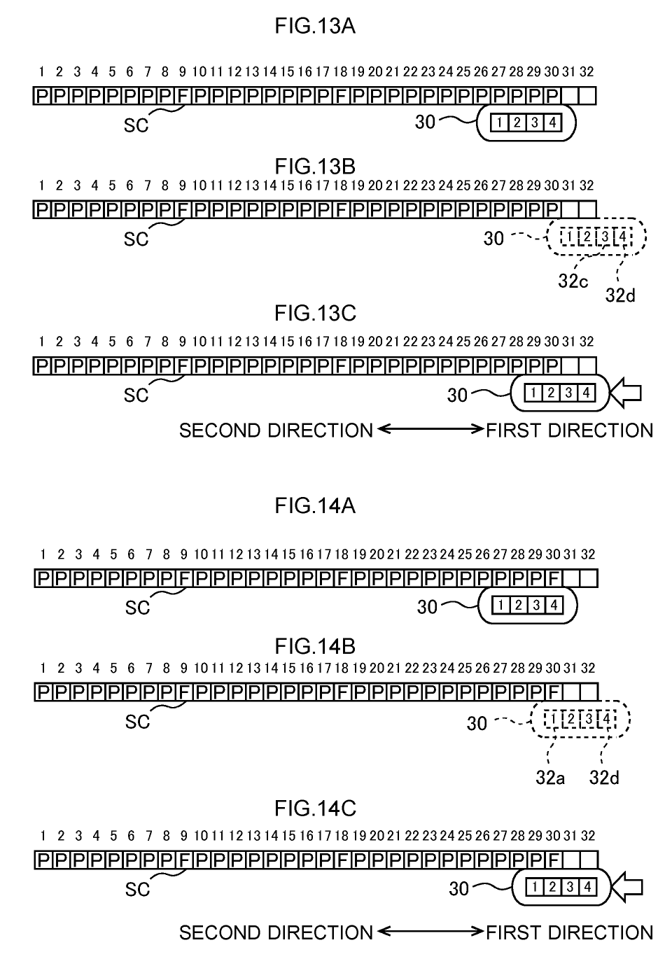

Here, the inspection apparatus 1 for the semiconductor wafer SW according to the first embodiment preferably performs inspection illustrated in FIGS. 13 and 14.

FIGS. 13A to 13C are second schematic views illustrating states of the inspection including the re-inspection according to the first embodiment, and illustrate states of the inspection in the specific row. In FIG. 9E, the semiconductor chip SC at Coordinate 29 is determined as the defective product. Thus, the contact is made between the semiconductor chip SC at Coordinate 29 and the first measurement site 32a so that the fourth measurement site 32d contacts the semiconductor chip SC at Coordinate 32 located at an end in the first direction.

However, as illustrated in FIG. 13A, for example, it is assumed that the semiconductor chip SC at Coordinate 29 is determined as a non-defective product. In this case, all the semiconductor chips SC at Coordinates 27 to 30 are non-defective products, and thus contact positions of the semiconductor chips SC are shifted by the number of the measurement sites, that is, four as illustrated in FIG. 13B. However, in this case, the number of semiconductor chips to be contacted becomes less than four, and the third and fourth measurement sites 32c and 32d do not contact any semiconductor chip SC.

There is a possibility that trouble occurs when any of the measurement sites 32 contacts the outside of the effective area EA or an area where the semiconductor chip SC is not formed during the inspection on the semiconductor chips SC. Thus, as illustrated in FIG. 13C, the contact position determination unit 91 determines to shift the contact positions in the second direction by the number of the semiconductor chips SC (two in FIGS. 13A to 13C) which is less than four. As a result, it is possible to suppress the occurrence of the trouble.

FIGS. 14A to 14C are third schematic views illustrating states of the inspection including the re-inspection according to the first embodiment, and illustrate states of the inspection in the specific row. In addition, as illustrated in FIG. 14A, for example, it is assumed that the semiconductor chip SC at Coordinate 30 is determined as a defective product. In this case, as illustrated in FIG. 14B, the contact position determination unit 91 determines the next contact positions such that contact is made between the semiconductor chip SC at Coordinate 30 and the first measurement site 32a. However, in this case, the number of semiconductor chips to be contacted becomes less than four, and the fourth measurement site 32d does not contact any semiconductor chip SC. Thus, as illustrated in FIG. 14C, the contact position determination unit 91 determines to shift the semiconductor chips SC in the second direction by the number (one in FIGS. 14A to 14C) of the semiconductor chips SC which is less than four. This also makes it possible to suppress the occurrence of the trouble.

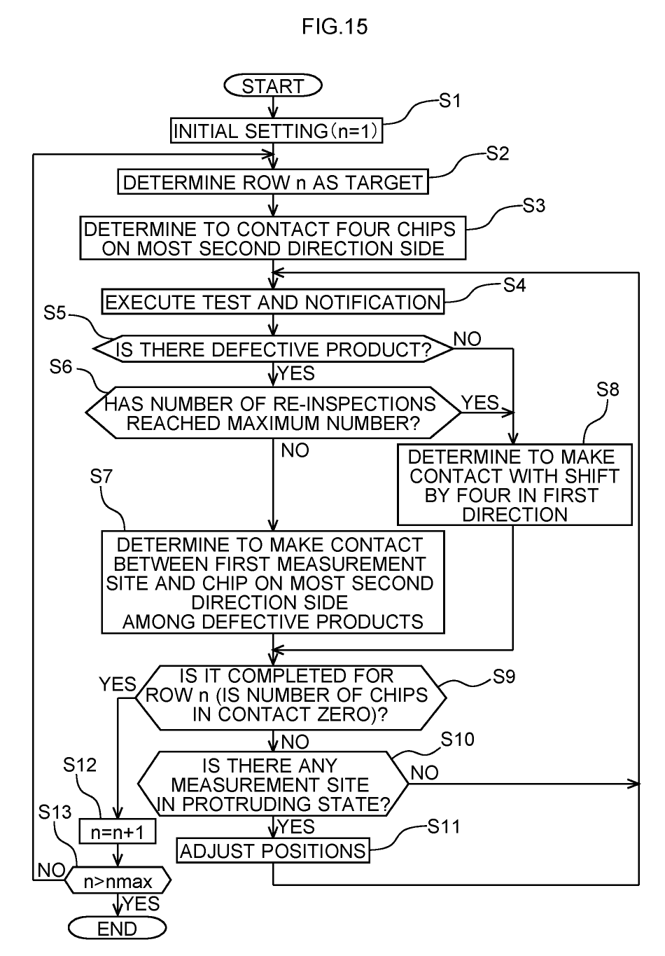

FIG. 15 is a flowchart illustrating the method for inspecting the semiconductor wafer SW according to the first embodiment. In FIG. 15, it is assumed that inspection is performed on each of the semiconductor chips SC of the semiconductor wafer SW in which the number of rows is nₘₐₓ.

As illustrated in FIG. 15, first, the controller 90 performs initial setting (S1). In this processing, the controller 90 loads a test program for performing the inspection on the semiconductor tester 80. Further, the controller 90 sets the semiconductor wafer SW on the prober P, sets the probe card 30, and adjusts a position of the probe card 30, and moves the probe card 30 to an initial position. In addition, a variable n is set to “1”. Further, arrangement information of a plurality of the semiconductor chips SC to be inspected is set in the contact position determination unit 91.

Next, the controller 90 determines the row n as an inspection target row (S2). Next, the contact position determination unit 91 determines to contact four semiconductor chips SC from the most second direction side among the semiconductor chips SC in the row n (S3). Then, the controller 90 makes the four measurement sites 32 contact the four semiconductor chips SC at determined positions, applies an electric signal from the semiconductor tester 80 to each of the semiconductor chips SC, and observes the response. Then, the semiconductor tester 80 determines whether each of the semiconductor chips SC is a non-defective product or a defective product (S4). Next, the semiconductor tester 80 notifies the contact position determination unit 91 of the determination result (S4).

Thereafter, the contact position determination unit 91 determines whether there is a defective product (S5). When there is a defective product (S5: YES), the contact position determination unit 91 determines whether the number of re-inspections has reached the maximum value (S6). When the number of re-inspections has not reached the maximum value (S6: NO), the contact position determination unit 91 determines to make contact between the first measurement site 32a and the semiconductor chip SC on the most second direction side among defective products (S7). Then, the processing proceeds to step S9.

On the other hand, when there is no defective product (S5: NO) or when the number of re-inspections has reached the maximum value (S6: YES), the contact position determination unit 91 determines to make contact with a shift by four in the first direction (S8). Then, the processing proceeds to step S9.

In step S9, the controller 90 determines whether the inspection is completed for all the semiconductor chips SC in the row n (S9). For example, in the inspection method according to the first embodiment, when the inspection is completed for all the semiconductor chips SC in the row n, the number of the semiconductor chips SC in contact with the four measurement sites 32 at positions determined by the contact position determination unit 91 is zero.

When the inspection is not completed for all the semiconductor chips SC in the row n (S9: NO), that is, when the four measurement sites 32 contact any of the semiconductor chips SC at the positions determined by the contact position determination unit 91, the contact position determination unit 91 determines whether any of the measurement sites 32 is in a protruding state (S10).

For example, in a case as illustrated in FIG. 13B or FIG. 14B, the contact position determination unit 91 determines that what is in the protruding state is present (S10: YES), and adjusts the contact position (S11). That is, the contact position determination unit 91 shifts the contact position in the second direction by the number of measurement sites 32 in the protruding state. Then, the processing proceeds to step S4. In a case other than the state illustrated in FIG. 13B or 14B, the contact position determination unit 91 determines that nothing is in the protruding state (S10: NO), and the processing proceeds to step S4.

When the inspection is completed for all the semiconductor chips SC in the row n (S9: YES), the controller 90 increases the variable n (S12). Next, the controller 90 determines whether the variable n exceeds nₘₐₓ (S13).

When the variable n does not exceed nₘₐₓ (S13: NO), the processing proceeds to step S2. On the other hand, when the variable n exceeds nₘₐₓ (S13: YES), the processing illustrated in FIG. 15 ends.

According to the above configuration, when the semiconductor chips SC determined as defective products are present among the N inspected semiconductor chips SC, the inspection apparatus 1 and the method for inspecting the semiconductor wafer SW determine the next contact target so as to make contact between the semiconductor chip SC located on the most second direction side among the semiconductor chips SC determined as the defective products and the measurement site 32 located on the most second direction side among the N measurement sites 32. Thus, when the semiconductor chips SC determined as the defective products are present, the semiconductor chips SC determined as the defective products are immediately re-inspected. As described above, since the re-inspection is sequentially performed on the semiconductor chips SC determined as the defective products, the number of times of contact can be reduced as compared with the conventional method and the efficient probing method. Therefore, it is possible to provide the inspection apparatus 1 for the semiconductor wafer SW capable of reducing the total number of contacts and reducing the inspection time and the manufacturing cost.

When the number of the remaining semiconductor chips SC to be contacted is less than N, the contact position determination unit 91 shifts the next contact positions in the second direction by a difference between the number and N. Thus, it is possible to reduce the possibility of occurrence of the trouble caused by one or more of the N measurement sites 32 on the first direction side not contacting the semiconductor chip SC.

The inspection apparatus 1 and the method for inspecting the semiconductor wafer SW can be achieved by the storage unit 92 according to the first embodiment.

Next, the inspection apparatus 1 and a method for inspecting the semiconductor wafer SW according to a second embodiment will be described. First, a plurality of semiconductor chips SC may include a semiconductor chip that has a defect generated in a formation step and damages the probe 31 when being contacted by the measurement site 32 or burns the probe 31 due to a large current flowing at the time of inspection. Such a semiconductor chip SC is referred to as a prohibited chip with which contact is prohibited.

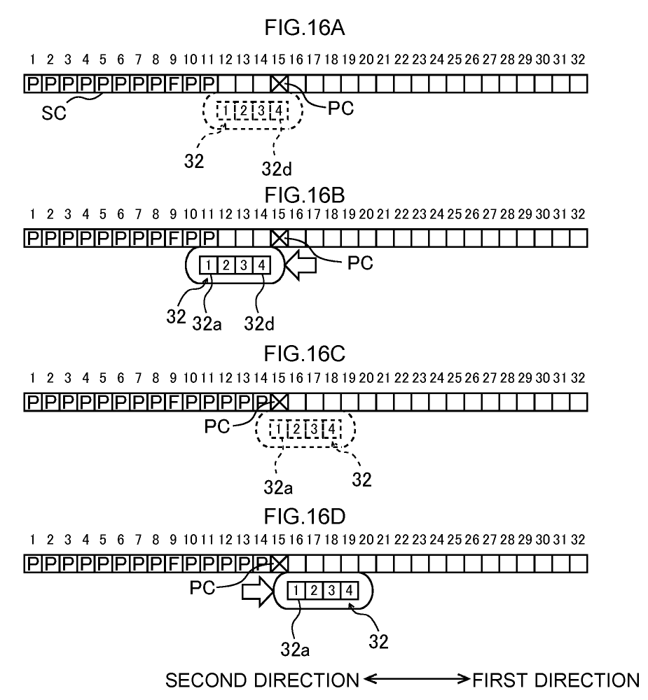

FIGS. 16A to 16D are first schematic views illustrating states of inspection including re-inspection according to the second embodiment, and illustrate states of the inspection in a specific row. For example, it is assumed that the semiconductor chip SC at Coordinate 15 is a prohibited chip PC. Here, as illustrated in FIG. 16A, it is assumed that the contact position determination unit 91 determines to make contact between the semiconductor chips SC at Coordinates 12 to 15 and the four measurement sites 32. In this case, the fourth measurement site 32d contacts the prohibited chip PC.

Therefore, as illustrated in FIG. 16B, the contact position determination unit 91 adjusts contact positions such that the fourth measurement site 32d (at an end in the first direction) among the four measurement sites 32 contacts the semiconductor chip SC (at Coordinate 14) adjacent to the prohibited chip PC in the second direction. As a result, the first measurement site 32a contacts the semiconductor chip SC at Coordinate 11 which has been already inspected, but it is possible to avoid the prohibited chip PC while inspecting the semiconductor chips SC at Coordinates 12 to 14 which have not been inspected.

In addition, as illustrated in FIG. 16C, it is assumed that the contact position determination unit 91 determines to make contact between the semiconductor chips SC at Coordinates 15 to 18 and the four measurement sites 32. In this case, the first measurement site 32a contacts the prohibited chip PC. It can be said that the semiconductor chips SC at Coordinates 1 to 14 have been already inspected in this state.

Therefore, as illustrated in FIG. 16D, the contact position determination unit 91 adjusts the contact positions such that the first measurement site 32a (at an end in the second direction) among the four measurement sites 32 contacts the semiconductor chip SC (at Coordinate 16) adjacent to the prohibited chip PC in the first direction. That is, since the inspection has been already performed on all the semiconductor chips SC on the second direction side of the prohibited chip PC, the contact positions of the four measurement sites 32 are further advanced by one in the first direction to adjust the contact positions. As a result, the prohibited chip PC can be avoided.

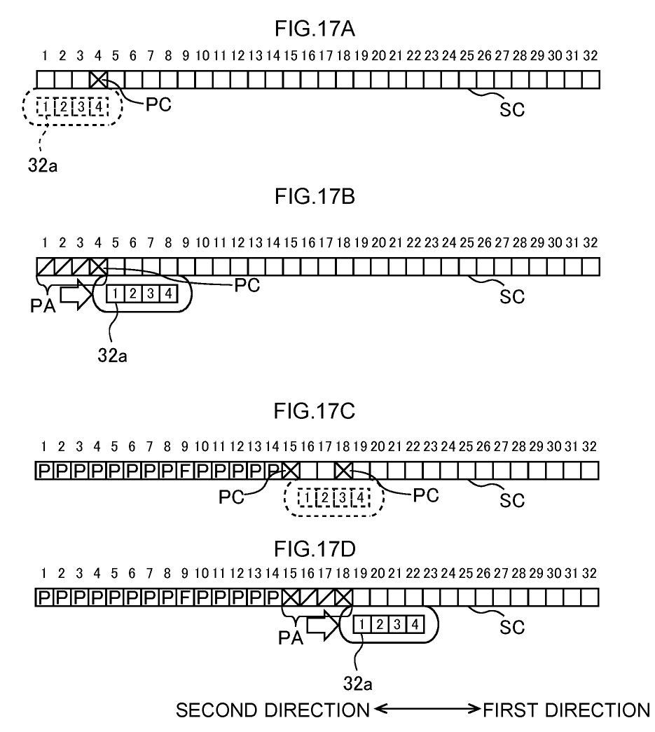

FIGS. 17A to 17D are second schematic views illustrating states of the inspection including the re-inspection according to the second embodiment, and illustrate states of the inspection in a specific row. As illustrated in FIG. 17A, for example, when the semiconductor chip SC at Coordinate 4 is a prohibited chip PC, the number of the semiconductor chips SC located in the second direction with respect to the prohibited chip PC is less than four. Thus, when an attempt is made to inspect the semiconductor chips SC at Coordinates 1 to 3 to avoid the prohibited chip PC, the first measurement site 32a does not contact any semiconductor chip SC. Therefore, as illustrated in FIG. 17B, the contact position determination unit 91 sets the prohibited chip PC and the semiconductor chips SC at Coordinates 1 to 3 as a prohibited area PA.

The contact position determination unit 91 then adjusts the contact positions to avoid the prohibited area PA. That is, in the example illustrated in FIG. 17A, since the number of the semiconductor chips SC located in the second direction with respect to the prohibited chip PC is less than four, the contact position determination unit 91 shifts the contact positions in the first direction as illustrated in FIG. 17B. As a result, the positions are adjusted so as to make contact between the first measurement site 32a and the semiconductor chip SC (at Coordinate 5) adjacent to the prohibited area PA in the first direction.

The contact position determination unit 91 similarly sets the prohibited areas PA also in a case where the number of the semiconductor chip SC located in the first direction with respect to the prohibited chip PC is less than four, such as a case where the prohibited chip PC is located at Coordinate 29. Then, when the inspection is completed for the semiconductor chips SC present on the second direction side of Coordinate 28, the inspection for the current row is ended, and inspection for the next row is performed.

In addition, for example, in a case where the contact positions are determined so as to avoid the prohibited chip PC as illustrated in FIG. 16D, there may be a case where another prohibited chip PC is contacted as illustrated in FIG. 17C. In such a case, as illustrated in FIG. 17D, the contact position determination unit 91 sets the two prohibited chips PC and the semiconductor chips SC at Coordinates 16 and 17 as the prohibited area PA. That is, when there is another prohibited chip PC among the four semiconductor chips SC located in the first direction or the second direction with respect to the prohibited chip PC, the two prohibited chip PC and the semiconductor chip SC therebetween are set as the prohibited area PA.

Then, the contact position determination unit 91 shifts the contact positions in the first direction. As a result, the positions are adjusted so as to make contact between the first measurement site 32a and the semiconductor chip SC (at Coordinate 19) adjacent to the prohibited area PA in the first direction.

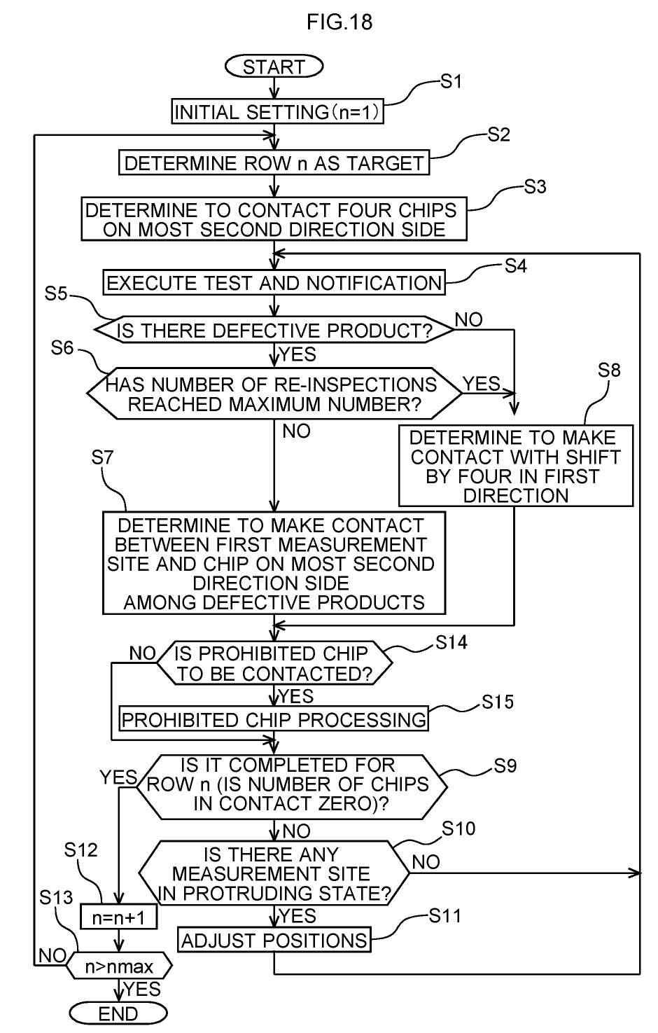

FIG. 18 is a flowchart illustrating the method for inspecting the semiconductor wafer SW according to the second embodiment.

After the process in step S7 or step S8, the contact position determination unit 91 determines whether the four measurement sites 32 are to contact the prohibited chip PC (S14). When the four measurement sites 32 are not to contact the prohibited chip PC (S14: NO), the processing proceeds to step S9.

On the other hand, when the four measurement sites 32 are to contact the prohibited chip PC (S14: YES), the contact position determination unit 91 executes processing related to the prohibited chip PC (S15). In this case, the processing described with reference to FIGS. 16A to 17D is executed. That is, in step S15, in a case where another prohibited chip PC is to be contacted, or contact with the four semiconductor chips SC is not to be made at the time of avoidance, a process of setting the prohibited area PA and avoiding the prohibited area PA is performed in addition to the avoidance of the prohibited chip PC. Then, the processing proceeds to step S9.

According to the above configuration, the inspection apparatus 1 for the semiconductor wafer SW, the inspection method, and the storage unit 92 according to the second embodiment can obtain the same effects as those of the first embodiment.

In the second embodiment, the contact position determination unit 91 adjusts the contact positions so as to make contact between the end of the N measurement sites 32 and the semiconductor chip SC adjacent to the prohibited chip PC in order to avoid the contact with the prohibited chip PC. Thus, all the N measurement sites 32 are prevented from contacting the prohibited chip PC, and it is possible to prevent failure due to the contact with the prohibited chip PC.

In addition, in a case where N semiconductor chips SC are not present between two prohibited chips PC or between the prohibited chip PC and the semiconductor chip SC at an end, the contact position determination unit 91 sets these as the prohibited area PA to prohibit contact. Thus, it is possible to further prevent erroneous contact with the prohibited chip PC and prevent the failure.

Next, the inspection apparatus 1 and a method for inspecting the semiconductor wafer SW according to a third embodiment will be described. In a case where re-inspection is performed on the semiconductor chip SC determined as a defective product in the initial inspection, it is empirically known that the possibility of being remedied increases when contact is made with the measurement site 32 different from the measurement site 32 that has made contact in the initial inspection.

Thus, the inspection apparatus 1 for the semiconductor wafer SW according to the third embodiment executes a process of causing the semiconductor chip SC determined as a defective product to be contacted by the measurement site 32 different from the measurement site 32 used in the previous contact. At this time, the contact position determination unit 91 may perform adjustment to shift the measurement sites 32 by one in the second direction, for example. In particular, the contact position determination unit 91 preferably determines as many semiconductor chips SC as possible to be initially inspected while performing the re-inspection. Further, in a case where a plurality of semiconductor chips SC to be re-inspected are present, the contact position determination unit 91 preferably performs determination such that each of the plurality of semiconductor chips SC to be re-inspected is contacted by the different measurement site 32 as much as possible.

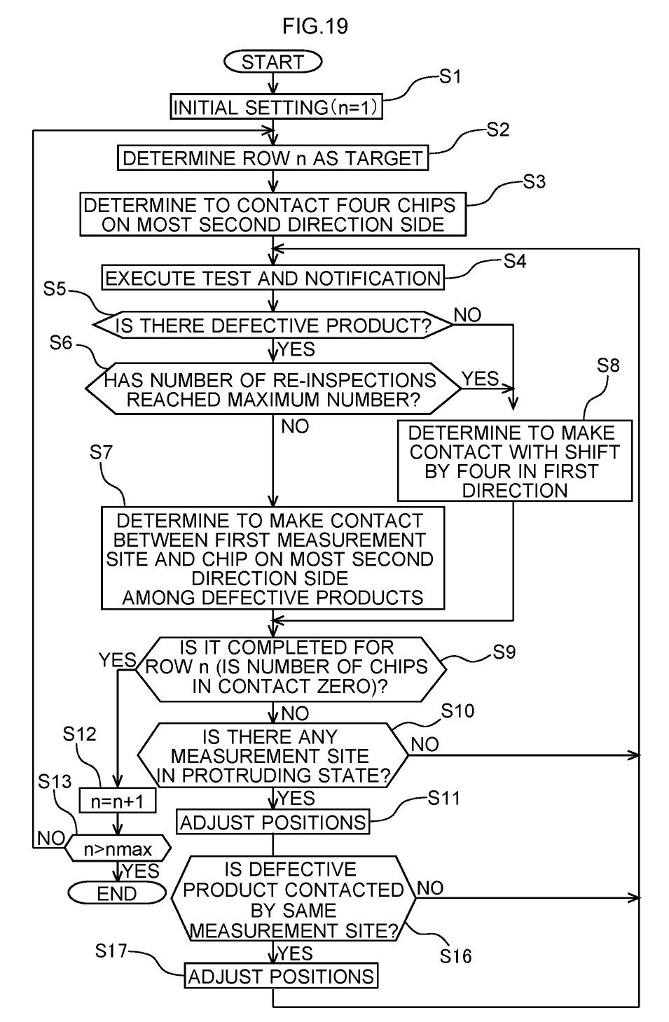

FIG. 19 is a flowchart illustrating the method for inspecting the semiconductor wafer SW according to the third embodiment.

After it is determined as “NO” in step S10 or after the process in step S11, the contact position determination unit 91 determines whether the semiconductor chip SC determined as a defective product is present and is contacted by the same measurement site 32 as that in the previous time (S16).

When the contact is not made with the same measurement site 32 as that in the previous time (S16: NO), the processing proceeds to step S4. On the other hand, when the contact is made with the same measurement site 32 as that in the previous time (S16: YES), the contact position determination unit 91 adjusts the contact positions (S17). Thereafter, the processing proceeds to step S4.

According to the above configuration, the inspection apparatus 1 for the semiconductor wafer SW, the inspection method, and the storage unit 92 according to the third embodiment can obtain the same effects as those of the first embodiment.

Since the semiconductor chip SC determined as a defective product is contacted by the different measurement site 32 at the time of the re-inspection, the possibility of being determined as the defective product due to a problem on the measurement site 32 side is alleviated, and the rate of being remedied the time of the re-inspection can be improved.

Next, the inspection apparatus 1 and a method for inspecting the semiconductor wafer SW according to a fourth embodiment will be described. In a case where the semiconductor chip SC is determined as a defective product in the initial inspection, the inspection apparatus 1 for the semiconductor wafer SW according to the fourth embodiment can discern a defect mode. The defect mode is obtained by categorizing content of a defect when the semiconductor chip SC is determined as a defective product during inspection.

Further, the inspection apparatus 1 for the semiconductor wafer SW according to the fourth embodiment performs re-inspection according to the defect mode when performing the re-inspection on the semiconductor chip SC determined as the defective product. That is, the inspection apparatus 1 performs the re-inspection on the semiconductor chip SC determined as the defective product under a different inspection condition. As a result, for example, it is possible to acquire detailed data for the semiconductor chip SC determined as the defective product and investigate the cause of the determination as the defective product. Alternatively, it is also possible to determine whether the semiconductor chip SC having performance slightly lower than the original performance of the semiconductor chip SC is a non-defective product or a defective product. In this case, it is also possible to improve the yield by remedying the semiconductor chip SC, which is a defective product according to the original standard, to be determined as a non-defective product with a lower grade.

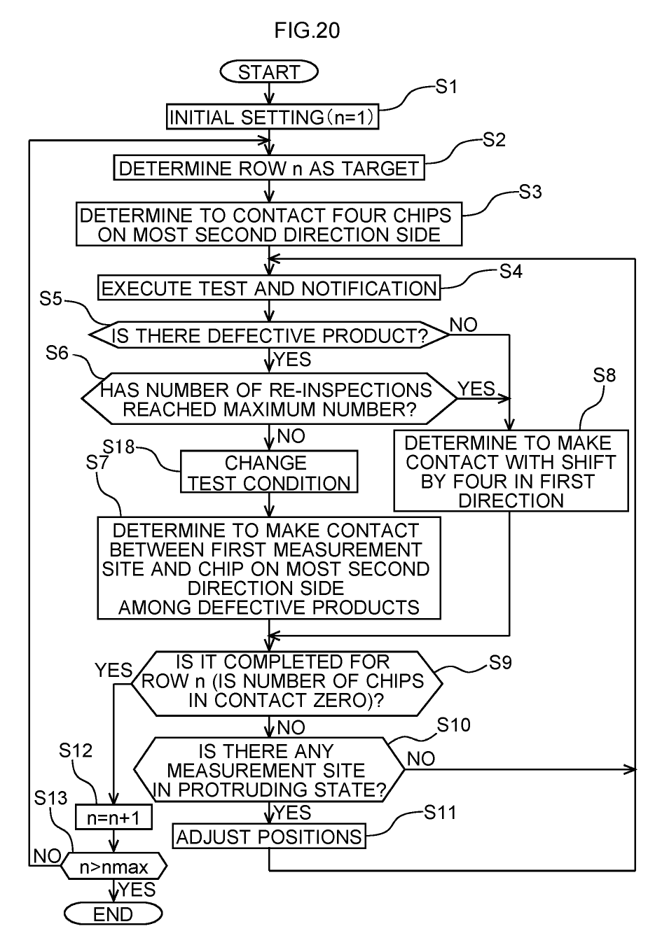

FIG. 20 is a flowchart illustrating the method for inspecting the semiconductor wafer SW according to the fourth embodiment.

After it is determined as “NO” in step S6, for example, the semiconductor tester 80 changes an inspection condition for the semiconductor chip SC, determined as a defective product based on an instruction from the controller 90, from that before the semiconductor chip SC is determined as the defective product (S18). For example, the semiconductor tester 80 may change an electric signal to be transmitted at the time of inspection, or may change a condition for determination on a non-defective product or a defective product of an output signal output from the semiconductor chip SC in response to the electric signal. As a result, it is possible to determine a non-defective product and a defective product in the lower grade. In addition, the inspection condition may be changed to content with which the cause of the defective product can be investigated. Then, the processing proceeds to step S7.

According to the above configuration, it is possible to obtain the same effects as those of the first embodiment by the inspection apparatus 1 for the semiconductor wafer SW, the inspection method, and the storage unit 92 according to the fourth embodiment.

The inspection apparatus 1 according to the fourth embodiment changes the inspection condition for the semiconductor chip SC determined as a defective product from that before the semiconductor chip SC is determined as the defective product. Thus, it is possible to investigate the cause of the determination as the defective product in the initial inspection or to perform the inspection in accordance with the lower grade, leading to the improvement of the yield.

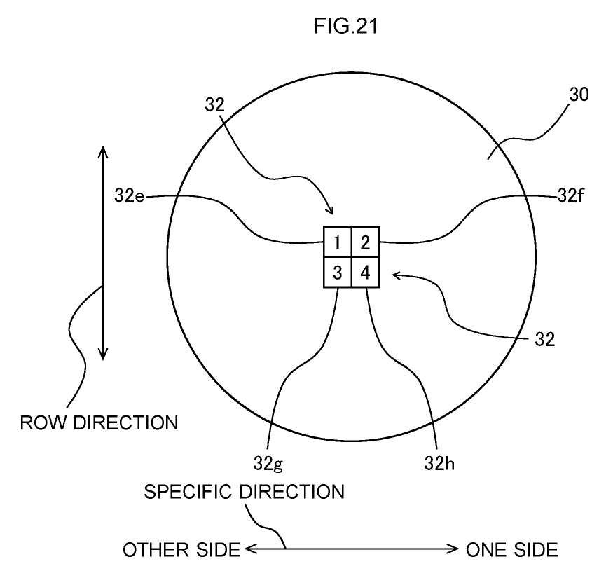

Next, the inspection apparatus 1 and a method for inspecting the semiconductor wafer SW according to a fifth embodiment will be described. FIG. 21 is a schematic view illustrating the probe card 30 of the inspection apparatus 1 for the semiconductor wafer SW according to the fifth embodiment. As illustrated in FIG. 21, in the probe card 30 in the fifth embodiment, N (for example, “2” in FIG. 21) measurement sites 32 are provided in each of M rows (M is an integer of two or more, for example, “2” in FIG. 21) in a row direction orthogonal to a specific direction. That is, the probe card 30 has M × N measurement sites 32.

In FIG. 21, out of the two measurement sites 32 in the first row, a first measurement site 32e is located on the other side, and a second measurement site 32f is located on one side. Further, out of the two measurement sites 32 in the second row, a third measurement site 32g is located on the other side, and a fourth measurement site 32h is located on the one side.

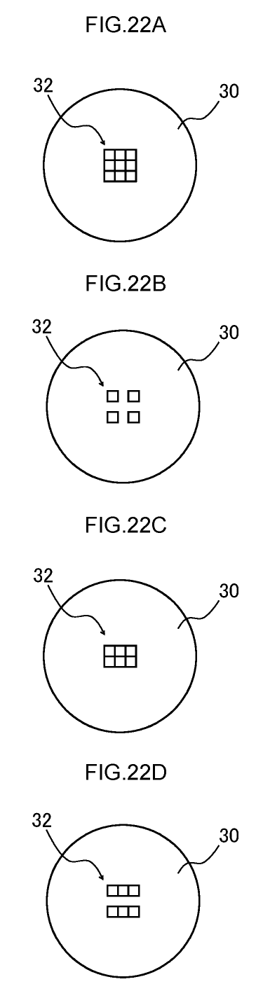

FIGS. 22A to 22D are schematic views illustrating other examples of the probe card 30 according to the fifth embodiment, in which FIG. 22A illustrates a first example, FIG. 22B illustrates a second example, FIG. 22C illustrates a third example, and FIG. 22D illustrates a fourth example.

As illustrated in FIG. 22A, the probe card 30 may have three measurement sites 32 in each of three rows. In addition, as illustrated in FIG. 22B, the probe card 30 may have two measurement sites 32 in each of two rows, the measurement sites 32 being provided with an interval in the specific direction (see FIG. 21) and an interval in the row direction (see FIG. 21) instead of an adjacent state. That is, the probe card 30 may be provided with two rows of two measurement sites 32 with the interval in each of the specific direction and the row direction.

Further, as illustrated in FIG. 22C, the probe card 30 may have three measurement sites 32 in each of two rows. In addition, as illustrated in FIG. 22D, the probe card 30 may have three measurement sites 32 in each of two rows, the measurement sites 32 being provided in an adjacent state in the specific direction and provided with an interval in the row direction. That is, the probe card 30 may be provided with two rows of three measurement sites 32 with the interval only in the row direction. Note that the probe card 30 may include the measurement sites 32 provided with an interval only in the specific direction and adjacent in the row direction.

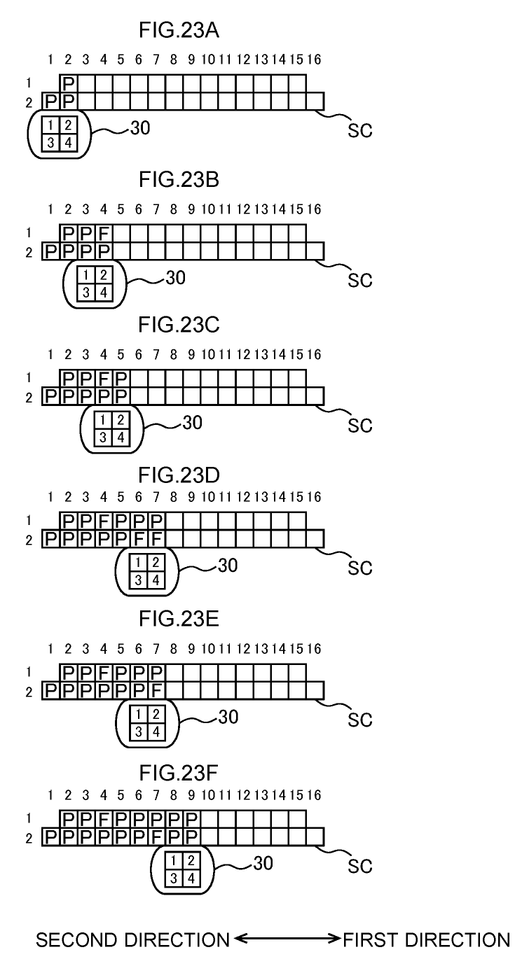

FIGS. 23A to 23F are schematic views illustrating states of inspection including re-inspection according to the fifth embodiment. In FIGS. 23A to 23F, it is assumed that the number of the semiconductor chips SC in a specific first row is fourteen, and the number of the semiconductor chips SC in a specific second row is sixteen. In addition, numbers of Coordinates 1 and 2 and 1 to 16 in the row direction and the specific direction are assigned to the semiconductor chips SC illustrated in FIGS. 23A to 23F. Further, it is assumed that the plurality of measurement sites 32 can simultaneously contact four (2 × 2) adjacent semiconductor chips SC, and the number of re-inspections is one time.

First, as illustrated in FIG. 23A, in the first inspection, the contact position determination unit 91 determines to make the probe card 30 contact the semiconductor chips SC at Coordinates (1, 2), (2, 1), and (2, 2). In this case, the semiconductor chip SC is not present at Coordinate (1, 1), and contact with the first measurement site 32e is not made. Then, the inspection is performed. It is assumed that all the semiconductor chips SC are determined as non-defective products in the first inspection.

Next, as illustrated in FIG. 23B, in the second inspection, the contact position determination unit 91 determines to make the probe card 30 contact the semiconductor chips SC at Coordinates (1, 3), (1, 4), (2, 3), and (2, 4). That is, since there is no semiconductor chip SC determined as a defective product in the first inspection, the contact position determination unit 91 determines to shift the semiconductor chips SC to be contacted next by two in the first direction without a shift in the row direction. Then, the inspection is performed. It is assumed that only the semiconductor chip SC at Coordinate (1, 4) is determined as a defective product in the second inspection.

Next, as illustrated in FIG. 23C, in the third inspection, the contact position determination unit 91 determines to make the probe card 30 contact the semiconductor chips SC at Coordinates (1, 4), (1, 5), (2, 4), and (2, 5). That is, the contact position determination unit 91 determines to make contact between the semiconductor chip SC at Coordinate (1, 4) determined as the defective product in the second inspection and the measurement site 32 (that is, the first measurement site 32e) located on the most second direction side. As a result, the semiconductor chip SC at Coordinate (1, 4) is subjected to the re-inspection, and the semiconductor chips SC at Coordinates (1, 5) and (2, 5) are subjected to the initial inspection. Then, it is assumed that the semiconductor chip SC at Coordinate (1, 4) is determined again as the defective product, and the semiconductor chips SC at Coordinates (1, 5) and (2, 5) are determined as non-defective products.

Thereafter, as illustrated in FIG. 23D, in the fourth inspection, the contact position determination unit 91 determines to make the probe card 30 contact the semiconductor chips SC at Coordinates (1, 6), (1, 7), (2, 6), and (2, 7). In the example illustrated in FIGS. 23A to 23F, the number of re-inspections is one. Thus, the semiconductor chip SC at Coordinate (1, 4) determined as the defective product in the re-inspection is not further subjected to the re-inspection. Therefore, the contact position determination unit 91 determines to make the probe card 30 contact the semiconductor chips SC at Coordinates (1, 6), (1, 7), (2, 6), and (2, 7) in the fourth inspection with a shift by two in the first direction without a shift in the row direction. Then, the inspection is performed. In the fourth inspection, it is assumed that the semiconductor chips SC at Coordinates (2, 6) and (2, 7) are determined as defective products, and the semiconductor chips SC at Coordinates (1, 6) and (1, 7) are determined as non-defective products.

Next, as illustrated in FIG. 23E, in the fifth inspection, the contact position determination unit 91 determines to make the probe card 30 contact the semiconductor chips SC at Coordinates (1, 6), (1, 7), (2, 6), and (2, 7). That is, the contact position determination unit 91 determines to make contact between one of the semiconductor chips SC at Coordinates (2, 6) and (2, 7), determined as the defective product, on the most second direction side and the measurement site 32 located on the most second direction side (that is, the third measurement site 32g) in the fourth inspection. At this time, the contact position determination unit 91 determines contact positions without a shift in the row direction. Then, the inspection is performed. In the fifth inspection, it is assumed that the semiconductor chip SC at Coordinate (2, 6) is determined as a non-defective product, but the semiconductor chip SC at Coordinate (2, 7) is determined again as the defective product.

Next, as illustrated in FIG. 23F, in the sixth inspection, the contact position determination unit 91 determines to make the probe card 30 contact the semiconductor chips SC at Coordinates (1, 8), (1, 9), (2, 8), and (2, 9). Here, the number of re-inspections is one in the example illustrated in FIGS. 23A to 23F. Thus, the semiconductor chip SC at Coordinate (2, 7) has been determined as the defective product in the fifth inspection, but additional re-inspection is not performed. Therefore, the contact position determination unit 91 determines to make the probe card 30 contact the semiconductor chips SC at Coordinates (1, 8), (1, 9), (2, 8), and (2, 9) in the sixth inspection with a shift by two in the first direction without a shift in the row direction. Then, the inspection is performed. It is assumed that all the semiconductor chips SC are determined as non-defective products in the sixth inspection. Thereafter, similarly to the above, inspection by the sequential method is performed on the semiconductor chips SC in the two rows.

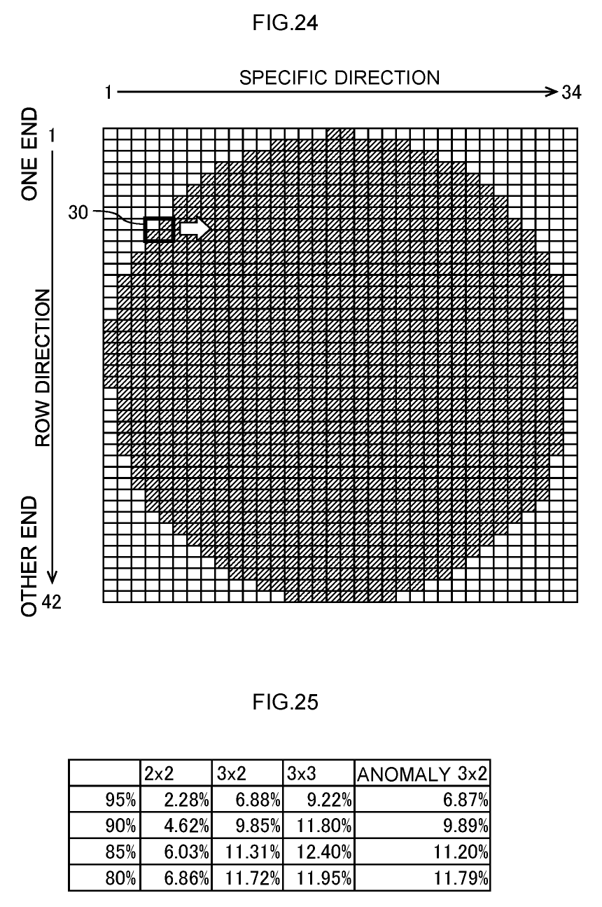

Next, results of simulation related to the number of times of contact will be described. FIG. 24 is a plan view illustrating the semiconductor wafer SW used in the simulation according to the fifth embodiment. In the simulation, as illustrated in FIG. 24, the number of times of contact of the probe card 30 is calculated in a case where inspection is performed on all the semiconductor chips SC formed in a grid shape to have a maximum of 34 in the specific direction and 42 rows in the row direction.

As for the arrangement of the measurement sites 32 of the probe card 30 used in the simulation, a total of 4 sites of 2 × 2 illustrated in FIG. 21, a total of 6 sites of 3 × 2 illustrated in FIG. 22C, a total of 9 sites of 3 × 3 illustrated in FIG. 22A, and a total of 6 sites of 3 × 2 with an interval in the row direction illustrated in FIG. 22D were applied. Note that what is illustrated in FIG. 22D is denoted as Anomaly 3 × 2.

In the simulation, defective chips in the initial inspection were randomly allocated to obtain four types of the percentage of non-defective products in the initial inspection of 95%, 90%, 85%, and 80%. The number of trials was 1000, and the number of re-inspections was one. As a method for evaluating the number of times of contact, the evaluation was performed based on a reduction rate of the number of times of contact according to the fifth embodiment with respect to the total number of times of contact according to the conventional method in which the initial inspection and the re-inspection are performed on preset contact positions. A larger numerical value means that the effect of reducing the number of times of contact according to the fifth embodiment is larger.

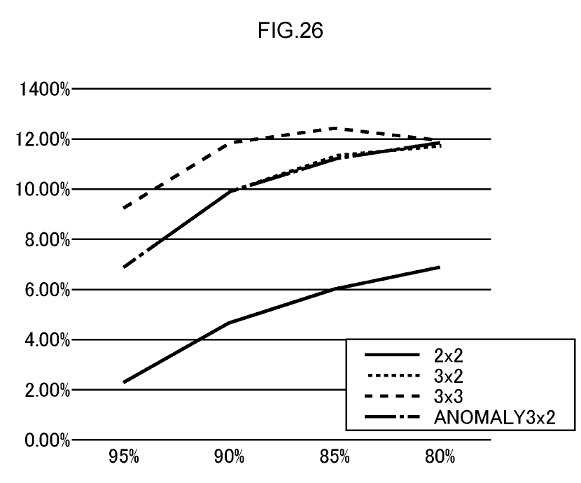

FIG. 25 is a table illustrating simulation results according to the fifth embodiment, and FIG. 26 is a graph illustrating the simulation results according to the fifth embodiment. First, with the measurement sites 32 having the arrangement of 2 × 2, the reduction rates of the total number of times of contact were 2.28%, 4.62%, 6.03%, and 6.86% for the percentages of non-defective products in the initial inspection of 95%, 90%, 85%, and 80%, respectively.

In addition, with the measurement sites 32 having the arrangement of 3 × 2, the reduction rates of the total number of times of contact were 6.88%, 9.85%, 11.31%, and 11.72% for the percentages of non-defective products in the initial inspection of 95%, 90%, 85%, and 80%, respectively. With the measurement sites 32 having the arrangement of 3 × 3, the reduction rates of the total number of times of contact were 9.22%, 11.80%, 12.40%, and 11.95% for the percentages of non-defective products in the initial inspection of 95%, 90%, 85%, and 80%, respectively.

Further, with the measurement sites 32 having the arrangement of Anomaly 3 × 2, the reduction rates of the total number of times of contact were 6.87%, 9.89%, 11.20%, and 11.79% for the percentages of non-defective products in the initial inspection of 95%, 90%, 85%, and 80%, respectively.

As described above, it has been found that the total number of times of contact is reduced in all the examples of the measurement sites 32. Therefore, it has been found that the total number of times of contact is also reduced when the N measurement sites 32 are provided in each of the M rows, and the inspection time and the manufacturing cost can be reduced.

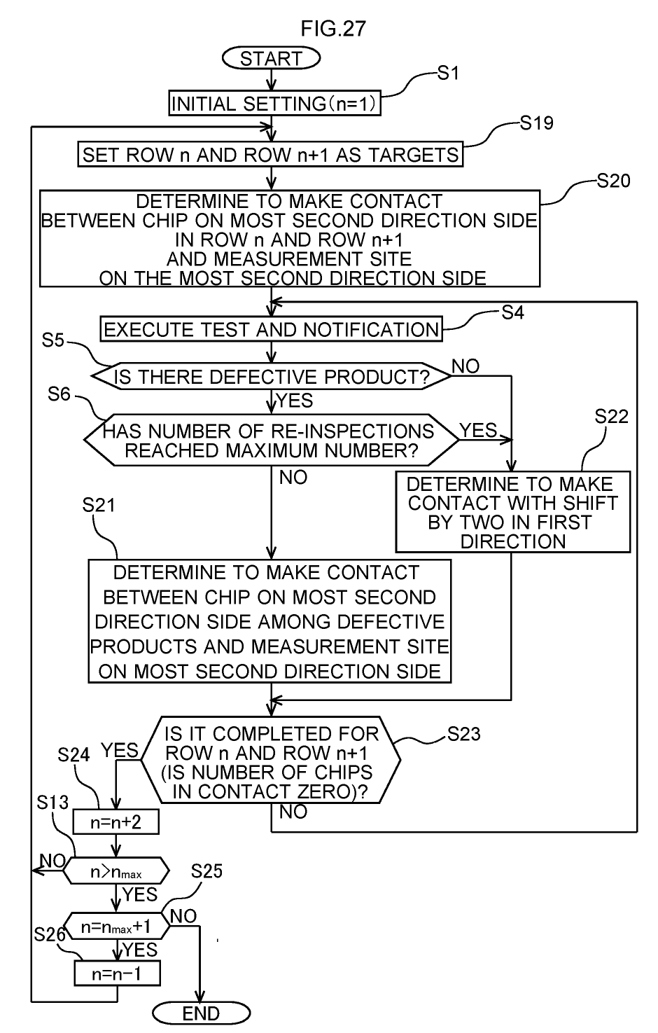

FIG. 27 is a flowchart illustrating the method for inspecting the semiconductor wafer SW according to the fifth embodiment. In FIG. 27, the measurement sites 32 are assumed to be 2 × 2. As illustrated in FIG. 27, first, the controller 90 performs initial setting similarly to the first embodiment, and sets the variable n to “1” (S1).

Next, the controller 90 determines a row n and a row n+1 (row n+M-1) as inspection target rows (S19). Next, the contact position determination unit 91 determines to make contact up to N × M semiconductor chips SC by making contact between the semiconductor chip SC on the most second direction side in the row n and the row n+1 and the measurement site 32 on the most second direction side (S20). Thereafter, the processing from steps S4 to S6 is executed.

Then, when there are defective products (S5: YES) and the number of re-inspections has not reached the maximum value (S6: NO), the contact position determination unit 91 determines to make contact between the semiconductor chip SC on the most second direction side among the defective products and the measurement site 32 on the most second direction side (S21). At this time, the contact position determination unit 91 determines contact positions without shifting the measurement sites 32 in the row direction. Then, the processing proceeds to step S23.

On the other hand, when there is no defective product (S5: NO) or when the number of re-inspections has reached the maximum value (S6: YES), the contact position determination unit 91 determines to make contact with a shift by two (N) in the first direction (S22). Also at this time, the contact position determination unit 91 determines the contact positions without shifting the measurement sites 32 in the row direction.

In step S23, the controller 90 determines whether the inspection is completed for all the semiconductor chips SC in the row n and the row n+1 (S23). In the inspection method according to the fifth embodiment, when the inspection is completed for all the semiconductor chips SC in the row n and the row n+1, the number of the semiconductor chips SC in contact with the measurement sites 32 at positions (that is, the positions in steps S21 and S22) determined by the contact position determination unit 91 is zero.

When the inspection is not completed for all the semiconductor chips SC in the row n and the row n+1 (S23: NO), that is, when any of the semiconductor chips SC is contacted by the measurement sites 32 at the positions determined by the contact position determination unit 91, the processing proceeds to step S4.

On the other hand, when the inspection is completed for all the semiconductor chips SC in the row n and the row n+1 (S23: YES), the controller 90 adds “2 (that is, M)” to the variable n (S24). Next, the controller 90 determines whether the variable n exceeds nₘₐₓ (S13).

When the variable n does not exceed nₘₐₓ (S13: NO), the processing proceeds to step S19. On the other hand, when the variable n exceeds nₘₐₓ (S13: YES), the controller 90 determines whether the variable n is nₘₐₓ + 1 (S25). When the variable n is nₘₐₓ + 1 (S25: YES), it can be said that only the semiconductor chips SC in a row nₘₐₓ are in an uninspected state. Therefore, the controller 90 subtracts “1” from the variable n (S26), and the processing proceeds to step S19. As a result, the inspection apparatus 1 for the semiconductor wafer SW according to the fifth embodiment prevents a situation in which the measurement sites 32 protrude in the row direction. That is, in the inspection apparatus 1 for the semiconductor wafer SW according to the fifth embodiment, the probe card 30 has the M rows of the measurement sites 32, and performs the inspection from one end to the other end in the row direction. In this case, when the number of the semiconductor chips SC to be inspected is less than M in the second half of the inspection or the like, the contact position determination unit 91 determines the contact positions so as to make contact between the measurement site 32 on the other end side in the row direction and the semiconductor chip SC on the other end side in the row direction.

On the other hand, when the variable n is not nₘₐₓ + 1 (S25: NO), the inspection has been performed up to the semiconductor chips SC in the row nₘₐₓ, and thus, the processing illustrated in FIG. 27 ends.

In the fifth embodiment, the controller 90 may execute the processes similar to steps S9 and S10 after the process in step S23. In this case, the controller 90 confirms whether contact is made between what is located on the most first direction side among the semiconductor chips SC to be contacted and the measurement site 32 on the most first direction side. Then, when the contact is not made between the semiconductor chip SC on the most first direction side and the measurement site 32 on the most first direction side, the contact position determination unit 91 shifts the contact positions toward the second direction side so as to make the contact therebetween.

According to the above configuration, it is possible to obtain the same effects as those of the first embodiment by the inspection apparatus 1 for the semiconductor wafer SW, the inspection method, and the storage unit 92 according to the fifth embodiment. In particular, in the fifth embodiment, it is possible to provide the inspection apparatus 1 for the semiconductor wafer SW capable of reducing the number of times of contact and reducing the inspection time and the manufacturing cost when the N measurement sites 32 are provided in the M rows.

Although the present disclosure has been described above based on the embodiments, the present disclosure is not limited to the above embodiments, and modifications may be made within a scope not departing from the scope of the present disclosure, or publicly known techniques, well-known techniques, or other techniques may be combined as appropriate within an acceptable scope. Further, techniques of the embodiments may be combined within an acceptable scope.

In addition, the flowcharts illustrated in FIGS. 15, 18 to 20, and 27 described above are merely examples, and the order and content of each processing may be appropriately changed within a scope not departing from the gist.

In addition, the probe card 30 is configured to inspect four continuous semiconductor chips SC in FIG. 4, but may be configured to perform the inspection on the discontinuous semiconductor chips SC at an interval without being particularly limited to the four continuous semiconductor chips SC.

In the inspection of the semiconductor chips SC, the zigzag movement as illustrated in FIG. 5 is not essential, and the inspection may be always performed from a specific direction, or may be performed in mixed directions by being performed on two rows from one side to the other side and then performed on one row from the other side to the one side. Further, the inspection may be performed while designating any row.

What is claimed is:

1. An inspection apparatus for a semiconductor wafer, comprising:
N (N is an integer of two or more) measurement sites arranged in at least a specific direction;
a tester configured to make the N measurement sites contact a plurality of semiconductor chips, formed on a semiconductor wafer and arrayed in the specific direction, and to inspect N semiconductor chips in a contact state among the plurality of semiconductor chips; and
a determination unit configured to determine semiconductor chips to be contacted by the N measurement sites among the plurality of semiconductor chips,
wherein the determination unit
in a case where there is no semiconductor chip determined as a defective product among the N inspected semiconductor chips, determines to shift semiconductor chips to be contacted next by N chips in a first direction which is one direction of the specific direction, and
in a case where there are one or more semiconductor chips determined as defective products among the N inspected semiconductor chips, determines the semiconductor chips to be contacted next in such a manner as to make contact between a semiconductor chip located closest to a side in a second direction among the one or more semiconductor chips determined as the defective products and a measurement site located closest to the side in the second direction among the N measurement sites, the second direction being another direction of the specific direction.

2. The inspection apparatus for a semiconductor wafer according to claim 1, wherein
in a case where a number of remaining semiconductor chips to be contacted among the plurality of semiconductor chips is less than N when the semiconductor chips to be contacted next are determined, the determination unit adjusts contact positions of the N semiconductor chips to be contacted next to be shifted in the second direction by a difference between the number and N.

3. The inspection apparatus for a semiconductor wafer according to claim 1, wherein
In a case where a prohibited chip, which is a semiconductor chip with which contact is prohibited, is to be contacted when the semiconductor chips to be contacted next are determined, the determination unit adjusts contact positions in such a manner as to make contact between a measurement site at an end in the first direction among the N measurement sites and a semiconductor chip adjacent to the prohibited chip in the second direction, or to make contact between a measurement site at an end in the second direction among the N measurement sites and a semiconductor chip adjacent to the prohibited chip in the first direction.

4. The inspection apparatus for a semiconductor wafer according to claim 3, wherein
the determination unit adjusts the contact positions to avoid a prohibited area by setting the prohibited area, in a case where a number of semiconductor chips located in the first direction or the second direction with respect to the prohibited chip is less than N, to include the prohibited chip and the semiconductor chips of which the number is less than N, or setting the prohibited area, in a case where N semiconductor chips located in the first direction or the second direction with respect to the prohibited chip includes another prohibited chip, to include the two prohibited chips and any semiconductor chip between the two prohibited chips.

5. The inspection apparatus for a semiconductor wafer according to claim 1, wherein
in a case where there is a semiconductor chip determined as a defective product among the N inspected semiconductor chips, the determination unit adjusts the contact positions in such a manner as to make contact between a measurement site, different from a measurement site having contacted the semiconductor chip determined as the defective product, and the semiconductor chip determined as the defective product.

6. The inspection apparatus for a semiconductor wafer according to claim 1, wherein
in a case where there is a semiconductor chip determined as a defective product among the N inspected semiconductor chips, the tester changes an inspection condition for the semiconductor chip determined as the defective product from an inspection condition applied before the determination as the defective product.

7. The inspection apparatus for a semiconductor wafer according to claim 1, wherein
the N measurement sites are provided in each of M rows (M is an integer of two or more) in a row direction which is a direction orthogonal to the specific direction,
the tester is capable of making the M rows of the N measurement sites contact a plurality of the semiconductor chips formed on the semiconductor wafer and arrayed in the specific direction and the row direction, and inspecting N × M semiconductor chips in the contact state, and
when semiconductor chips to be contacted by the M rows of the N measurement sites are determined among the plurality of semiconductor chips and the N × M semiconductor chips are inspected, the determination unit determines
in a case where there is no semiconductor chip determined as a defective product among the N × M inspected semiconductor chips, to shift semiconductor chips to be contacted next by N chips in the first direction without a shift in the row direction, and
in a case where there are one or more semiconductor chips determined as defective products among the N × M inspected semiconductor chips, to make contact between a semiconductor chip located closest to the side in the second direction among the one or more semiconductor chips determined as the defective products and a measurement site located closest to the side in the second direction among the M rows of the N measurement sites without shifting the semiconductor chips to be contacted next in the row direction.

8. A method for inspecting a semiconductor wafer by an inspection apparatus, which includes N (N is an integer of two or more) measurement sites arranged in at least a specific direction and a tester that makes the N measurement sites contact a plurality of semiconductor chips, formed on a semiconductor wafer and arrayed in the specific direction, and inspects N semiconductor chips in a contact state among the plurality of semiconductor chips, the method comprising
a determination step of determining semiconductor chips to be contacted by the N measurement sites among the plurality of semiconductor chips,
wherein in the determination step,
in a case where there is no semiconductor chip determined as a defective product among the N inspected semiconductor chips, semiconductor chips to be contacted next are determined to be shifted by N chips in a first direction which is one direction of the specific direction, and
in a case where there are one or more semiconductor chips determined as defective products among the N inspected semiconductor chips, the semiconductor chips to be contacted next are determined in such a manner as to make contact between a semiconductor chip located closest to a side in a second direction among the one or more semiconductor chips determined as the defective products and a measurement site located closest to a side in a second direction among the N measurement sites, the second direction being another direction of the specific direction.

9. A non-transitory computer readable medium storing an inspection program for causing a computer to function as the inspection apparatus for a semiconductor wafer according to claim 1.
